(19) United States
(12) Patent Application Publication
(10) Pub. No.: US 2025/0239304 A1
(43) Pub. Date: Jul. 24, 2025

(54) MEMORY DEVICE, METHOD OF MANUFACTURING, AND INTEGRATED CIRCUIT DEVICE

(71) Applicant: TAIWAN SEMICONDUCTOR MANUFACTURING COMPANY, LTD., Hsinchu (TW)

(72) Inventors: Huai-Ying HUANG, Hsinchu (TW); Yu-Ming LIN, Hsinchu (TW)

(21) Appl. No.: 18/661,000

(22) Filed: May 10, 2024

Related U.S. Application Data
(60) Provisional application No. 63/622,383, filed on Jan. 18, 2024.

(51) Int. Cl. G11C 15/04; H01L 23/522; H01L 23/528; H01L 29/417

(52) U.S. Cl. CPC G11C 15/043; H01L 23/5223; H01L 23/5226; H01L 23/528; H01L 23/5283; H10D 64/258

(57) ABSTRACT

A memory device includes a memory cell having a first transistor, a second transistor, a first capacitor and a second capacitor coupled with each other into a data storage circuit configured to store a datum. The memory cell further has a third transistor and a fourth transistor coupled with each other into a comparison circuit configured to perform a comparison of the datum stored in the data storage circuit with a search input datum. The memory device further includes a back-end-of-line (BEOL) structure. The BEOL structure includes at least a part of the memory cell.

### RELATED APPLICATION(S)

This application claims the benefit of U.S. Provisional Application No. 63/622,383, filed Jan. 18, 2024, which is herein incorporated by reference in its entirety.

### BACKGROUND

Recent developments in the field of artificial intelligence (AI) have resulted in various products and/or applications, including, but not limited to, speech recognition, image processing, machine learning, natural language processing, or the like. Such products and/or applications often use neural networks to process large amounts of data for learning, training, cognitive computing, or the like. Memory devices configured to perform computing-in-memory (CIM) operations (also referred to herein as CIM memory devices) are usable for neural network applications, as well as other applications. A CIM memory device includes a memory array configured to store weight data and/or input data to be used together in one or more CIM operations. Content addressable memories (CAMs) belong to a category of CIM memories that are configured to perform fast search operations, such as those for pattern matching applications, network switches, network routers, data-intensive applications, or the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory device, in accordance with some embodiments.

FIGS. 2A-2C are schematic diagrams of memory devices, in accordance with some embodiments.

FIG. 3A is a schematic perspective view of an integrated circuit (IC) device, in accordance with some embodiments.

FIG. 3B is a schematic cross-sectional view of an IC device, in accordance with some embodiments.

FIG. 4 is a schematic view of a layout of a memory cell, in accordance with some embodiments.

FIGS. 5A-5D are schematic cross-sectional views of a region of an IC device, in accordance with some embodiments.

FIGS. 6A-6D are schematic cross-sectional views of an IC device at various stages during a manufacturing process, in accordance with some embodiments.

FIGS. 7A-7C are flowcharts of various methods, in accordance with some embodiments.

FIG. 8A is a schematic diagram of an integrated circuit (IC) device, in accordance with some embodiments.

FIG. 8B is a schematic diagram of a neural network, in accordance with some embodiments.

FIG. 9 is a block diagram of an electronic design automation (EDA) system in accordance with some embodiments.

FIG. 10 is a block diagram of an IC device manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a memory cell in a content addressable memory (CAM) array has a configuration including four transistors and two capacitors (4T2C). In at least one embodiment, at least a part of the CAM array is formed in a back-end-of-line (BEOL) structure and/or is manufactured by BEOL processes. In one or more embodiments, an entirety of the CAM array is formed in a BEOL structure and/or is manufactured by BEOL processes. Compared to other approaches in which a memory cell of a CAM array is a static random-access memory (SRAM) including 10 transistors (10T SRAM) or 16 transistors (16T SRAM), a CAM array including 4T2C memory cells (or a 4T2C CAM array), in accordance with some embodiments, occupies a smaller chip area and includes fewer elements with lower power consumption. Further, in one or more embodiments where a 4T2C CAM array is partly or wholly included in a BEOL structure, additional chip areas on a substrate are freed up for front-end-of-line (FEOL) circuitry, such as a memory controller or other logic circuitry. In at least one embodiment, the capacitors in a 4T2C CAM array are physically stacked upon transistors of the 4T2C CAM array which further reduces an area of the 4T2C CAM array. Further advantages are achievable in one or more devices, methods, and/or operations, as described herein.

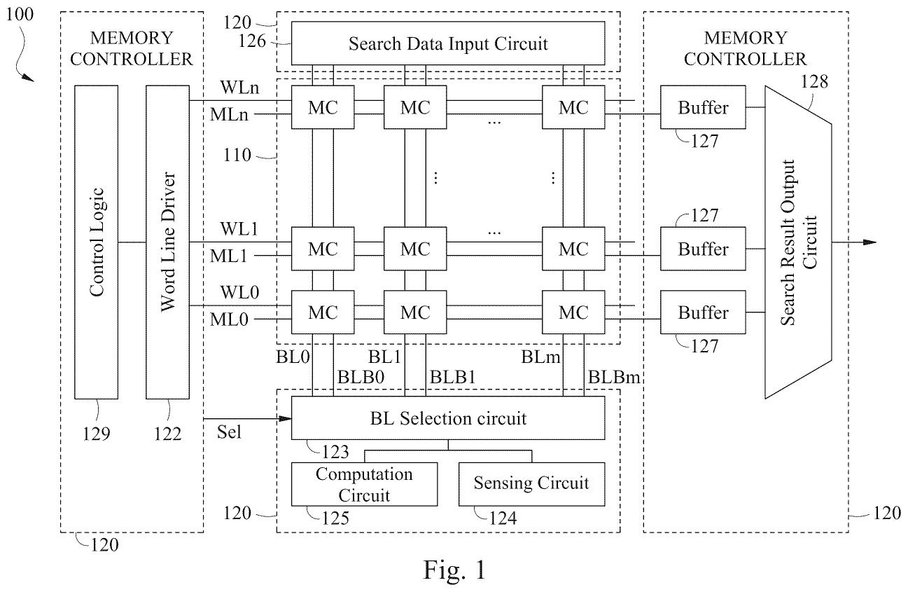

FIG. 1 is a schematic diagram of a memory device 100, in accordance with some embodiments. A memory device is a type of integrated circuit (IC) device. In at least one embodiment, a memory device is an individual IC device. In some embodiments, a memory device is included as a part of a larger IC device which comprises circuitry other than the memory device for other functionalities.

The memory device 100 comprises a memory array 110, and a memory controller 120. The memory array 110 comprises a plurality of memory cells MC arranged in a plurality of columns and rows of the corresponding memory array. The memory array 110 further comprises a plurality of word lines (also referred to as “address lines”) extending along a row direction (i.e., the horizontal direction in FIG. 1) of the rows, a plurality of bit lines (also referred to as “data lines”) extending along a column direction (i.e., the vertical direction in FIG. 1) of the columns, and a plurality of match lines extending along the row direction. The memory controller 120 is electrically coupled, by the word lines, bit lines, and match lines to the memory cells MC and configured to control access operations of the memory cells MC including, but not limited to, a read operation, a write operation, a CIM operation, a search operation, or the like.

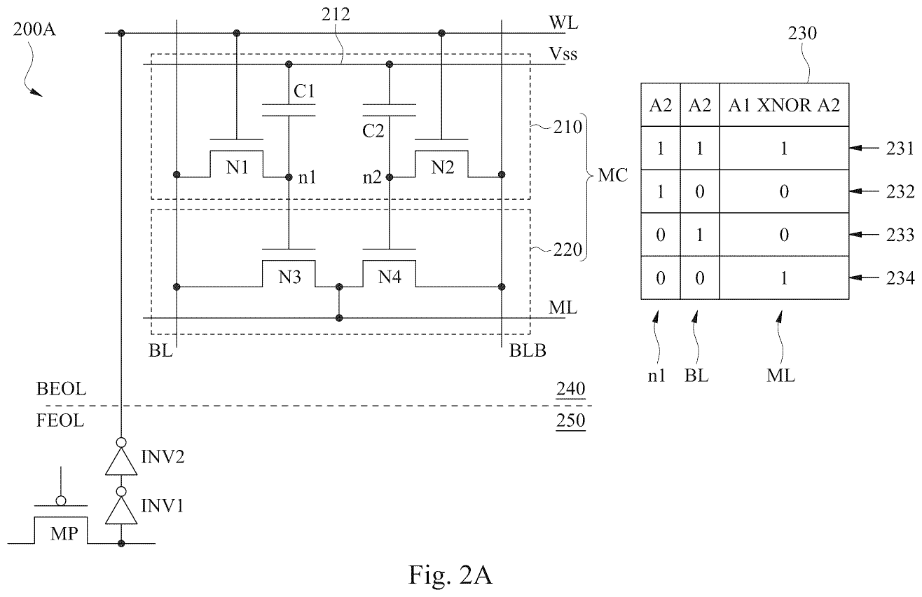

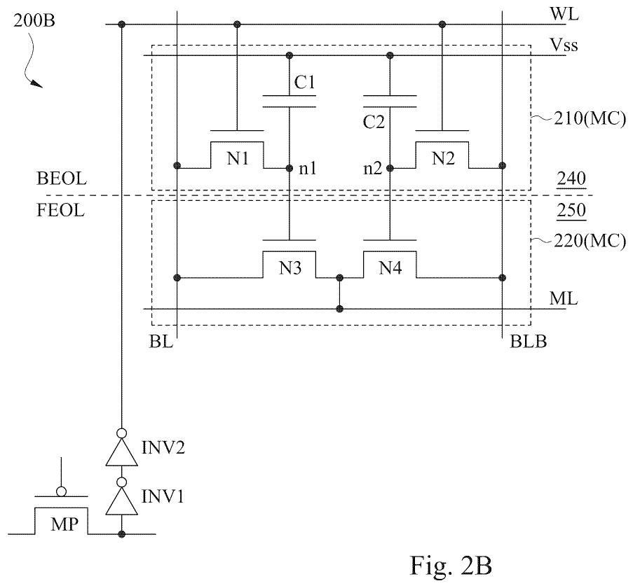

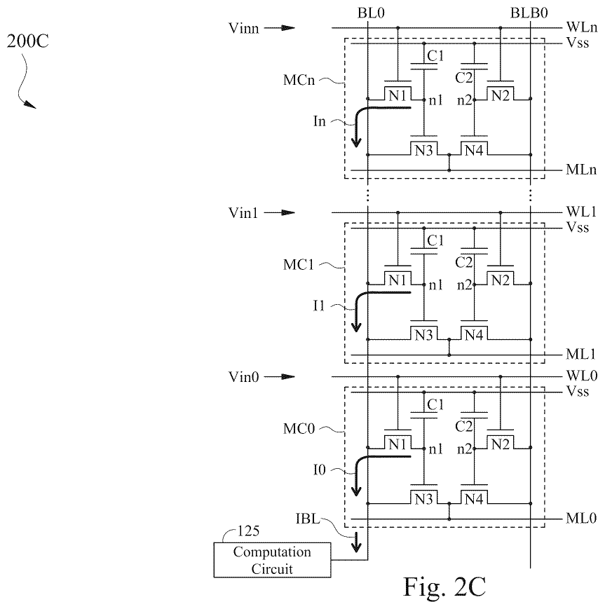

In the example configuration in FIG. 1, the word lines comprise a plurality of word lines WL0, WL1 to WLn, the bit lines comprise a plurality of pairs of bit lines BL0 and BLB0, BL1 and BLB1, to BLm and BLBm, and the match lines comprise a plurality of match lines ML0, ML1 to MLn, where m and n are non-negative integers. The word lines are sometimes commonly referred to herein as “WL”, the bit lines are sometimes commonly referred to herein as “BL” and/or “BLB”, and the match lines are sometimes commonly referred to as “ML”. In some example operations, word lines are configured for transmitting addresses of the memory cells MC to be read from in a read operation, or for transmitting addresses of the memory cells MC to be written to in a write operation, or for transmitting input voltages to memory cells MC in a CIM operation, or the like. In some example operations, bit lines are configured for transmitting data read from the memory cells MC indicated by corresponding word lines, or for transmitting data to be written to the memory cells MC indicated by corresponding word lines, or for transmitting bit line currents in a CIM operation, or for transmitting search input signals corresponding to search input data in a search operation, or the like. In some example operations, match lines are configured for transmitting results of a search operation, or the like. In the memory device 100, each memory cell MC is coupled to a word line WL, a pair of bit lines BL and BLB, and a match line ML. An example memory cell configuration of each memory cell MC is described with respect to FIG. 2A. In some embodiments, the memory array 110 comprises a plurality of source lines (not shown) coupled to the memory cells MC along the rows or along the columns. Source lines are further examples of data lines, and are sometimes commonly referred to herein as “SL”. Various memory cell configurations and/or numbers of word lines and/or bit lines and/or match lines and/or source lines in a memory array are within the scope of various embodiments.

The memory controller 120 is sometimes referred to as a control circuit. In the example configuration in FIG. 1, the memory controller 120 comprises a word line driver 122, a BL selection circuit 123, a sensing circuit 124, a computation circuit 125, a search data input circuit 126, buffers 127, a search result output circuit 128, and a control logic 129. In some embodiments, the memory controller 120 further comprises one or more of pre-charging circuits, clock generators for providing clock signals for various components of the memory device 100, global address decoder circuits, pre-decoder circuits, address latches, pulse generators, timing circuits, one or more input/output (I/O) circuits for data, address, clock and/or control exchange with external circuitry, one or more sub-controllers for controlling various operations in the memory device 100, or the like.

The word line driver 122 is coupled to the memory array 110 via the word lines WL. The word line driver 122 is configured to decode a row address of the memory cell MC selected to be accessed in an access operation. The word line driver 122 is sometimes referred to as a word line decoder. The word line driver 122 is configured to supply a voltage to the selected word line WL corresponding to the decoded row address, and a different voltage to the other, unselected word lines WL. In at least one embodiment, the word line driver 122 comprises one or more driving circuits or inverters.

In some embodiments, the memory controller 120 comprises a bit line driver (not shown) coupled to the memory array 110 via the bit lines BL and/or the bit lines BLB. In some embodiments, the bit line driver is selectively coupled to the bit lines BL and/or the bit lines BLB through the BL selection circuit 123. The bit line driver is configured to decode a column address of the memory cell MC selected to be accessed in an access operation. The bit line driver is sometimes referred to as a bit line decoder. The bit line driver is configured to supply a voltage to the selected bit line BL and/or BLB corresponding to the decoded column address, and a different voltage to the other, unselected bit lines BL and/or BLB. In at least one embodiment, the bit line driver comprises one or more driving circuits or inverters. In some embodiments, the memory controller 120 further comprises a source line driver (not shown) coupled to the memory cells MC via source lines (not shown). In one or more embodiments, one or more of the word line driver 122, the bit line driver, the source line driver are part of circuitry referred to as a read/write driver or a read/write decoder.

In the example configuration in FIG. 1, the BL selection circuit 123 is configured to selectively couple one or more of the bit lines BL and/or BLB to one of the sensing circuit 124, and the computation circuit 125. In some embodiments, the BL selection circuit 123 is configured to switch one or more of the bit lines BL and/or BLB among the sensing circuit 124, the computation circuit 125, the search data input circuit 126, and/or the bit line driver. In at least one embodiment, the BL selection circuit 123 is configured to have a switched state in which one or more of the bit lines BL and/or BLB are not coupled to any of the sensing circuit 124, the computation circuit 125, the search data input circuit 126, and the bit line driver. The BL selection circuit 123 is coupled to the memory controller 120 which is configured to output a control signal Sel to the BL selection circuit 123 to control switching of the BL selection circuit 123. In one or more embodiments, the BL selection circuit 123 comprises a switch, a transistor, a multiplexer, or the like. For example, the memory controller 120 is configured to supply the control signal Sel to a gate or a control terminal/pin/input of the BL selection circuit 123.

The sensing circuit 124 is configured to perform a read operation, when coupled to a selected bit line BL by the BL selection circuit 123. In some embodiments, the sensing circuit 124 comprises a sense amplifier. In at least one embodiment, the sensing circuit 124 further comprises a buffer for temporarily storing data. Example buffers include, but are not limited to, latches, registers, memory cells, or other circuit elements configured for data storage. Other configurations of the sensing circuit 124 and/or buffers are within the scopes of various embodiments. In a read operation in one or more embodiments, the sensing circuit 124 is configured to sense a read current on the bit line coupled to a selected memory cell MC and the sensing circuit 124. The sensing circuit 124 or a further circuit of the memory controller 120 is configured to output a datum stored in and read from the selected memory cell MC, based on the sensed read current.

The computation circuit 125 is configured to perform a CIM operation including a computation involving input data and weight data stored in the memory array 110. In some embodiments, a CIM operation is different from a search operation which involves a comparison of search input data with data stored in the memory array 110. In at least one embodiment, the computation circuit 125 comprises one or more of a current summation circuit, a multiply-accumulate (MAC) circuit, or the like. A current summation circuit is configured to perform a summation of a bit line current on a bit line coupled to the current summation circuit, e.g., by the BL selection circuit 123. In some embodiments, a current summation circuit comprises an integrator circuit. In an example, an integrator circuit is electrically coupled to a bit line to receive the bit line current thereon, and is configured to, based on the bit line current, generate an output voltage having a voltage value corresponding to a current value of the bit line current. In at least one embodiment, it is easier in subsequent processing to use the voltage value of the output voltage than to use the current value of the bit line current to determine a result of the CIM operation. Other configurations of the current summation circuit are within the scopes of various embodiments. In some embodiments, a MAC circuit comprises one or more accumulators and one or more analog-to-digital converters (ADCs). Example accumulators include, but are not limited to, resistors, capacitors, integrator circuits, operational amplifiers, combinations thereof, or the like. Example ADCs include, but are not limited to, logics, integrated circuits, comparators, counters, registers, combinations thereof, or the like. In some embodiments, the computation circuit 125 is omitted.

The search data input circuit 126 is configured to supply search input signals corresponding to search input data to the bit lines BL and/or BLB in a search operation. Example circuits of the search data input circuit 126 include, but are not limited to, registers, drivers, or the like. In some embodiments, a same diver or driving circuit is configured as the search data input circuit 126 in a search operation, and as a bit line driver in a write operation.

In an example search operation, the search data input circuit 126 is configured to supply search input signals corresponding to search input data, e.g., an input vector or a search word of (m+1) bits, correspondingly to the bit lines BL0, BL1 to BLm. The search word is compared, bit by bit, with (n+1) words stored in the memory array 110. Each of the (n+1) words includes (m+1) bits each stored in a corresponding memory cell in a row coupled to a common word line WL. For example, the memory cells, or a row of memory cells, coupled to the word line WL0 together store one of the (n+1) stored words, the memory cells, or another row of memory cells, coupled to the word line WL1 together store another of the (n+1) stored words, or the like. When all bits of the search word match all corresponding bits of a stored word in a row of memory cells, a match line ML corresponding to the row of memory cell has a first logic state, e.g., one of logic “1” and logic “0”. When any bit of the search word does not match a corresponding bit of a stored word in a row of memory cells, the match line ML corresponding to the row of memory cell has a second logic state, e.g., the other of logic “1” and logic “0”. For example, when all bits of the search word match all corresponding bits of the stored word in the row of memory cells coupled to the word line WL0, the corresponding match line ML0 has a first logic state, e.g., logic “1”, indicating a match. For a further example, when any bit of the search word does not match a corresponding bit of the stored word in the row of memory cells coupled to the word line WL1, the corresponding match line ML1 has a second logic state, e.g., logic “0”, indicating a no-match. In some embodiments, the search word and each stored word long and include more than 1000 bits. Further details of a search operation at the memory cell level are described with respect to FIG. 2A.

The buffers 127 are correspondingly coupled to the match lines ML and are configured to temporarily store the logic states on the match lines ML. The search result output circuit 128 is coupled to the buffers 127 to receive the buffered logic states of the match lines ML, and output the address of each match line ML having the corresponding logic state indicting a match. In some embodiments, the search result output circuit 128 is configured to output a signal, a number, or another type of information, corresponding to each match line ML having a match. The logic states on the match lines ML are an example or form of the search result of the search operation. The output of the search result output circuit 128 is another example or form of the search result. An example circuit of the search result output circuit 128 comprises a multiplexer. Other circuit configurations of the search result output circuit 128 are within the scopes of various embodiments. In some embodiments, the buffers 127 and/or the search result output circuit 128 are omitted or replaced with other circuits in the memory controller 120.

The control logic 129 is an example of one or more sub-controllers and/or further circuits included in the memory controller 120, and is configured to control other components and various operations in the memory device 100. In the example configuration in FIG. 1, the control logic 129 is coupled to the word line driver 122, and is configured to control the word line driver 122 in an access operation, including a read operation, a write operation, and/or a CIM operation, as described herein. The control logic 129, or one or more further sub-controllers and/or further circuits of the memory controller 120, is/are coupled to and configured to control one or more of the BL selection circuit 123, sensing circuit 124, computation circuit 125, search data input circuit 126, search result output circuit 128, a bit line driver, pre-charging circuits, buffers, I/O circuits, or the like, to coordinate operations of these circuits, drivers and/or buffers in various access operations of the memory device 100. In one or more embodiments, the control logic 129 comprises one or more circuits of one or more of transistors, switches, logic gates, multiplexers, flip-flops, latches, or the like. The described configurations of memory arrays and/or memory controllers are examples. Other memory array and/or memory controller configurations are within the scopes of various embodiments.

FIG. 2A is a schematic diagram of a memory device 200A, in accordance with some embodiments. Components in FIG. 2A having corresponding components in FIG. 1 are designated by the same reference numerals as in FIG. 1.

In some embodiments, the memory device 200A corresponds to the memory device 100, and comprises a memory array and a memory controller. A memory cell MC is illustrated in FIG. 2A as an example of memory cells in the memory array. A transistor MP, and two inverters INV1, INV2 are illustrated in FIG. 2A as example circuit elements of the memory controller or other logic circuitry. Other memory cells and circuit elements of the memory device 200A are omitted for simplicity.

The memory cell MC comprises a data storage circuit 210, and a comparison circuit 220. The data storage circuit 210 is configured to store a datum, or bit. The comparison circuit 220 is configured to perform a comparison of the datum stored in the data storage circuit 210 with a search input datum. In the example configuration in FIG. 2A, the memory cell MC comprises a first transistor N1, a second transistor N2, a first capacitor C1 and a second capacitor C2 coupled with each other into the data storage circuit 210. The memory cell MC further comprises a third transistor N3 and a fourth transistor N4 coupled with each other into the comparison circuit 220. The memory cell MC in FIG. 2A with four transistors and two capacitors is sometimes referred to as a 4T2C memory cell, and a memory array comprising 4T2C memory cells is sometimes referred to as a 4T2C memory array. The memory cell MC is coupled to a word line WL, a match line ML, and a pair of bit lines including a first bit line BL and a second bit line BLB.

The data storage circuit 210 comprises a first node n1 and a second node n2, in addition to the transistors N1, N2 and the capacitors C1, C2. The transistor N1 comprises a gate coupled to the word line WL, a first source/drain coupled to the node n1, and a second source/drain coupled to the bit line BL. The transistor N2 comprises a gate coupled to the word line WL, a first source/drain coupled to the node n2, and a second source/drain coupled to the bit line BLB. The capacitor C1 comprises a first electrode coupled to the node n1, and a second electrode coupled to a reference node 212 configured to carry a reference voltage. The capacitor C2 comprises a first electrode coupled to the node n2, and a second electrode coupled to the reference node 212. In some embodiments, the reference voltage is the ground voltage (VSS), and/or the reference node 212 is configured as a ground power rail. Other non-zero values of the reference voltage and/or other configurations of the reference node 212 are within the scopes of various embodiments. The node n1 is configured to store a first logic state corresponding to the datum, or bit, stored in the data storage circuit 210, and the node n2 is configured to store a second logic state corresponding to the datum and different from the first logic state. In an example, when the logic state at the node n1 is logic “1”, the logic state at the node n2 is logic “0”. In another example, when the logic state at the node n1 is logic “0”, the logic state at the node n2 is logic “1”.

In the comparison circuit 220, the transistor N3 comprises a gate coupled to the node n1, a first source/drain coupled to the match line ML, and a second source/drain coupled to the bit line BL. The transistor N4 comprises a gate coupled to the node n2, a first source/drain coupled to the match line ML, and a second source/drain coupled to the bit line BLB. In the example configuration in FIG. 2A, the transistors N1-N4 are N-type transistors. In some embodiments, at least one of the transistors N1-N4 is a P-type transistor.

Various access operations are performed, e.g., under control of the memory controller, in memory cells of the memory device 200A. Example access operations include, but are not limited to, a search operation, a write operation, a read operation, a CIM operation, or the like.

In a search operation, the memory cell MC is configured to perform a XOR or XNOR logic operation. A truth table 230 of the XNOR operation is illustrated in FIG. 2A. The XNOR operation has two inputs A1, A2 corresponding to the logic states at the node n1 and the bit line BL, and an output A1 XNOR A2 corresponding to a logic state on the match line ML. The logic state at the node n1 corresponds to the datum, or bit, stored in the memory cell MC. The logic state on the bit line BL corresponds to a search input datum, or search bit, in a search word input to the memory array comprising the memory cell MC, as described with respect to FIG. 1. The logic state on the match line ML corresponds to a comparison result of a comparison between the bit stored in the memory cell MC and the corresponding search bit of the search word. When the search bit matches the stored bit, e.g., at rows 231, 234 of the truth table 230, the logic state on the match line is logic “1” indicating a match. When the search bit does not match the stored bit, e.g., at rows 232, 233 of the truth table 230, the logic state on the match line is logic “0” indicating a no-match.

In a first example, logic “1” corresponding to the stored bit is at the node n1, and an inverted version of the stored bit, i.e., logic “0”, is at the node n2. Logic “1”, e.g., a positive voltage, such as a power supply voltage VDD, at the node n1 is supplied to the gate of the transistor N3, and turns ON the transistor N3. Logic “0”, e.g., VSS, at the node n2 is supplied to the gate of the transistor N4, and turns OFF the transistor N4. As a result, the bit line BL is coupled through the turned ON transistor N3 to the match line ML, whereas the bit line BLB is isolated by the turned OFF transistor N4 from the match line ML. The match line ML is pre-charged, e.g., by a pre-charging circuit, to a positive voltage, e.g., VDD.

In a situation corresponding to the row 231 of the truth table 230, logic “1” corresponding to a search bit in a search word is supplied, e.g., through a search data input circuit 126 as described with respect to FIG. 1, to the bit line BL. For example, a positive voltage, e.g., VDD, corresponding to logic “1” is supplied to the bit line BL. An inverted version of the search bit, i.e., logic “0”, is supplied by the search data input circuit 126 to the bit line BLB. For example, VSS corresponding to logic “0” is supplied to the bit line BLB, e.g., the bit line BLB is grounded. Because the pre-charged match line ML is already at VDD, VDD on the bit line BL coupled to the match line ML through the turned ON transistor N3 does not cause a change, or a detectable change, in the voltage of the match line ML, indicating a match of the search bit and the stored bit.

In a situation corresponding to the row 232 of the truth table 230, logic “0” corresponding to a search bit in a search word is supplied to the bit line BL. For example, VSS is supplied to the bit line BL, e.g., the bit line BL is grounded. An inverted version of the search bit, i.e., logic “1” or VDD, is supplied to the bit line BLB. The grounded bit line BL is coupled to the match line ML through the turned ON transistor N3, and pulls the voltage of the match line ML from the pre-charged voltage VDD to VSS, indicating a no-match of the search bit and the stored bit.

In a second example, logic “0” corresponding to the stored bit is at the node n1, and logic “1” is at the node n2. Logic “1”, e.g., VDD, at the node n2 is supplied to the gate of the transistor N4, and turns ON the transistor N4. Logic “0”, e.g., VSS, at the node n1 is supplied to the gate of the transistor N3, and turns OFF the transistor N3. As a result, the bit line BLB is coupled through the turned ON transistor N4 to the match line ML, whereas the bit line BL is isolated by the turned OFF transistor N3 from the match line ML. The match line ML is pre-charged by the pre-charging circuit, to a positive voltage, e.g., VDD.

In a situation corresponding to the row 233 of the truth table 230, logic “1”, or VDD, corresponding to a search bit in a search word is supplied to the bit line BL, and logic “0” is supplied to the bit line BLB, e.g., the bit line BLB is grounded. The grounded bit line BLB is coupled to the match line ML through the turned ON transistor N4, and pulls the voltage of the match line ML from the pre-charged voltage VDD to VSS, indicating a no-match of the search bit and the stored bit.

In a situation corresponding to the row 234 of the truth table 230, logic “0” corresponding to a search bit in a search word is supplied to the bit line BL, e.g., the bit line BL is grounded, and logic “1”, or VDD, is supplied to the bit line BLB. Because the pre-charged match line ML is already at VDD, VDD on the bit line BLB coupled to the match line ML through the turned ON transistor N4 does not cause a change, or a detectable change, in the voltage of the match line ML, indicating a match of the search bit and the stored bit.

If every search bit of the search word matches a stored bit in a corresponding memory cell coupled to the match line ML, as described with respect to the situations at rows 231, 234 of the truth table 230, the voltage on the match line ML remains at VDD and is detected, or output, e.g., by a search result output circuit 128 as described with respect to FIG. 1, as a match of the search word by a stored word corresponding to the match line ML, i.e., the stored word in the memory cells coupled to the match line ML. However, if at least one search bit does not match a stored bit in a corresponding memory cell coupled to the match line ML, the voltage on the match line ML is pulled down to VSS as described with respect to the situations at rows 232, 233 of the truth table 230. VSS on the match line ML is detected, or output, by the search result output circuit 128, as a no-match of the search word by the stored word corresponding to the match line ML. In at least one embodiment, after the completion of the search operation, the bit lines BL, BLB are restored to a low voltage, e.g., VSS. In the described example search operation, the memory cell MC is configured to perform an XNOR operation. In some embodiments, the memory cell is configured to perform an XOR operation, in a similar manner.

In an example write operation of the memory cell MC, a write circuit or a bit line driver is coupled, e.g., by a BL selection circuit 123 as described with respect to FIG. 1, to the bit line BL and bit line BLB. An access voltage is supplied, e.g., by a word line driver 122 as described with respect to FIG. 1, to the gates of the transistors N1, N2 to turn ON the transistors N1, N2. In some embodiments, to write logic “1” to the memory cell MC, the write circuit or bit line driver supplies VDD to the bit line BL and VSS to the bit line BLB. As a result, the capacitor C1 is charged to have a charged voltage VDD at the node n1, whereas any charge in the capacitor C2 is discharged to the ground through the bit line BLB resulting in the capacitor C2 being uncharged with the node n2 at VSS. In some embodiments, to write logic “0” to the memory cell MC, the write circuit or bit line driver supplies VSS to the bit line BL and VDD to the bit line BLB. As a result, any charge in the capacitor C1 is discharged to the ground through the bit line BL resulting in the capacitor C1 being uncharged with the node n1 at VSS, whereas the capacitor C2 is charged to have a charged voltage VDD at the node n2. Examples of data written by one or more write operations into the memory array of the memory device 200A include, but are not limited to, stored words to be searched in a search operation, weight data to be computed with input data in a CIM operation, data to be read out in a read operation as in a regular memory, or the like. In at least one embodiment, the match line is not used in a write operation, e.g., the match line ML is floating.

In an example read operation of the memory cell MC, the memory controller of the memory device 200A controls the BL selection circuit 123, by an appropriate control signal Sel, to couple the sensing circuit 124 to one of the bit line BL and bit line BLB. For example, the bit line BL is coupled to the sensing circuit 124, whereas the bit line BLB is floating. The memory controller further controls a pre-charging circuit to pre-charge the bit line BL to a pre-charged voltage between a power supply voltage (e.g., VDD) and a reference voltage (e.g., VSS or ground). In an example, the pre-charged voltage is VDD/2. The memory controller further controls the word line driver 122 to supply, to the word line WL, an access voltage to turn ON the transistor N1. The transistor N2 is turned ON, too, however, the floating bit line BLB does not affect the read operation, in one or more embodiments. As the transistor N1 is turned ON, the pre-charged voltage on the bit line BL changes in accordance with a charging state of the capacitor C1, i.e., the datum stored in the memory cell MC.

When the memory cell MC stores logic “1”, the capacitor C1 is charged with a charged voltage VDD at the node n1. As a result, the pre-charged voltage on the bit line BL is increased from VDD/2 toward VDD. In this process, the capacitor C1 loses at least part of its charge. In the sensing circuit 124, a sense amplifier coupled to the bit line BL detects and amplifiers the voltage increase on the bit line BL, and outputs a read signal indicating that the datum, or bit, read from the memory cell MC is logic “1”. In this amplifying process, the sense amplifier also supplies VDD to the bit line BL to restore the capacitor C1 back to the charged state with the charged voltage VDD at the node n1, i.e., to rewrite the read out logic “1” back to the memory cell MC.

When the memory cell MC stores logic “0”, the capacitor C1 is not charged, with VSS at the node n1. As a result, the pre-charged voltage on the bit line BL is decreased from VDD/2 toward VSS. In this process, the capacitor C1 is partly charged. In the sensing circuit 124, the sense amplifier coupled to the bit line BL detects and amplifiers the voltage decrease on the bit line BL, and outputs a read signal indicating that the datum, or bit, read from the memory cell MC is logic “0”. In this amplifying process, the sense amplifier also supplies VSS to the bit line BL to discharge any charges accumulated in the capacitor C1 due to the read operation, and to restore the capacitor C1 back to the discharged state with VSS at the node n1, i.e., to rewrite the read out logic “0” back to the memory cell MC. In some embodiments, the described read operation is performed periodically for all memory cells, not to output data from the memory cells, but to refresh the data stored therein. A reason is that capacitors in memory cells potentially lose their charges, and stored data, over time. In at least one embodiment, the described read operation is performed through the bit line BLB instead of the bit line BL. In some embodiments, the described read operation is performed through both the bit line BL and the bit line BLB. In some embodiments, read operations are performed to verify whether the stored words or weight data have been correctly written into the memory array of the memory device 200A, or to access data as in a regular memory, or the like. In at least one embodiment, the match line is not used in a read operation, e.g., the match line ML is floating.

In the example configuration in FIG. 2A, the memory array comprising the memory cell MC and similarly configured memory cells is entirely included in a BEOL structure 240, as schematically illustrated in FIG. 2A. The memory controller of the memory device 200A and/or other logic circuitry, which are schematically represented by the transistor MP and inverters INV1, INV2, are included in an FEOL structure 250 and are sometimes referred to as FEOL circuitry. In some embodiments, a part of the memory controller and/or other logic circuitry is included in the BEOL structure 240.

In the memory device 200A, because the memory array is included in the BEOL structure 240, additional chip areas on a substrate of the FEOL structure 250 are freed up for the FEOL circuitry, or the area of the FEOL circuitry is reduced. In some embodiments, by configuring the memory array in the BEOL structure 240, it is possible to reduce the area of the FEOL circuitry by 60% or greater. In one or more embodiments, it is possible to achieve one or more advantages including, but not limited to, a reduced size of the memory device 200A, availability of additional circuits and/or functionality in the FEOL circuitry, stackable high-packing-density low-cost CAM devices, or the like. In at least one embodiment, the described 4T2C memory configuration provides at least comparable performance to, yet with lower standby leakage and/or lower power consumption than, a memory configuration in accordance with other approaches, e.g., 10T SRAM or 16T SRAM. One reason is that the 4T2C memory configuration includes fewer transistors than the other approaches. Another reason is that the 4T2C memory configuration includes, as described herein, BEOL transistors which have lower standby leakage than FEOL transistors used in the memory configuration in accordance with the other approaches. Further advantages are achievable in one or more embodiments, as described herein.

FIG. 2B is a schematic diagram of a memory device 200B, in accordance with some embodiments. In some embodiments, the memory device 200B corresponds to one or more of the memory devices 100, 200A. Components in FIG. 2B having corresponding components in FIG. 2A are designated by the same reference numerals as in FIG. 2A.

Compared to the memory device 200A which has a memory array entirely formed in a BEOL structure, the memory device 200B comprises a memory array partially formed in a BEOL structure 240. For example, as schematically illustrated in FIG. 2B, each memory cell MC in the memory array of the memory device 200B has the data storage circuit 210 formed in the BEOL structure 240, and the comparison circuit 220 formed in the FEOL structure 250. In other words, the transistors N1, N2 and capacitors C1, C2, are correspondingly BEOL transistors and BEOL capacitors, whereas the transistors N3, N4 are FEOL transistors. By including at least a part (rather than a whole) of the memory cell MC, as well as the memory array of the memory device 200B, in the BEOL structure 240, it is still possible, in one or more embodiments, to achieve size reduction and/or other advantages as described herein.

FIG. 2C is a schematic diagram of a memory device 200C, in accordance with some embodiments. In some embodiments, the memory device 200C corresponds to one or more of the memory devices 100, 200A, 200B. Components in FIG. 2C having corresponding components in FIGS. 1, 2A are designated by the same reference numerals as in FIGS. 1, 2A.

The memory device 200C is an example of a memory device configured to, in addition to one or more of write operations, read operations, search operations as described with respect to FIG. 2A, perform a CIM operation which includes a computation involving input data and weight data stored in a memory array of the memory device 200C.

In the example configuration in FIG. 2C, a column of the memory array of the memory device 200C is illustrated, whereas other columns of the memory array are omitted for simplicity. The column includes memory cells MC0, MC1 to MCn coupled to a common pair of bit lines BL0, BLB0. Each of the memory cells MC0, MC1 to MCn is a 4T2C memory cell as described with respect to FIG. 2A, and is coupled to a corresponding word line and a corresponding match line. For example, the memory cells MC0, MC1 to MCn are coupled correspondingly to word lines WL0, WL1 to WLn, and correspondingly to match lines ML0, ML1 to MLn.

In an example CIM operation, the bit line BL0 is coupled, e.g., through a BL selection circuit (not shown), to a computation circuit 125 as described with respect to FIG. 1. A memory controller (not shown) of the memory device 200C supplies input voltages Vin0, Vin1 to Vinn correspondingly to the word lines WL0, WL1 to WLn. The match lines ML0, ML1 to MLn are not used in the CIM operation, e.g., the match lines ML0, ML1 to MLn are floating. In some embodiments, multiple columns of the memory array are accessed in the same CIM operation, in a manner similar to that described herein with respect to the column corresponding to the bit line BL0.

In some embodiments, the input voltages Vin0, Vin1 to Vinn correspond to input data to be computed, e.g., multiplied, with the weight data stored in the memory array of the memory device 200C. In some embodiments, the input voltages Vin0, Vin1 to Vinn are simultaneously supplied to the corresponding word lines WL0, WL1 to WLn. In response to the input voltages supplied to the plurality of word lines, the memory cells are configured to output corresponding currents to the bit line BL0. For example, in response to the input voltage Vin0, the memory cell MC0 is caused to output a current I0 to the bit line BL0. The current I0 corresponds to the input voltage Vin0, and a bit stored in the memory cell MC0 (e.g., a voltage of the node n1). Similarly, in response to the input voltage Vin1, the memory cell MC1 is caused to output a current I1 to the bit line BL0, and in response to the input voltage Vinn, the memory cell MCn is caused to output a current In to the bit line BL0. The currents I0, I1 to In output by the memory cells MC0, MC1 to MCn in response to the input voltages Vin0, Vin1 to Vinn are collected on the bit line BL0 as a bit line current IBL which is a sum of the currents I0, I1 to In output by the memory cells MC0, MC1 to MCn, i.e., IBL=I0+I1+. . . In. In at least one embodiment, the bit line current IBL corresponds to a product of input data corresponding to the input voltages Vin0, Vin1 to Vinn and weight data stored in the memory cells MC0, MC1 to MCn. The memory controller of the memory device 200C is configured to determine the product based on a current value of the bit line current IBL.

In some embodiments, the input voltages Vin0, Vin1 to Vinn are the same voltage sufficient to turn on the transistors N1 of the memory cells MC0, MC1 to MCn. For example, the input voltages Vin0, Vin1 to Vinn correspond to the access voltage for a read operation described with respect to FIG. 2A. In at least one embodiment, the input voltages Vin0, Vin1 to Vinn are sequentially supplied to the corresponding word lines WL0, WL1 to WLn. As a result of the application of the input voltages Vin0, Vin1 to Vinn, the bits of weight data stored in the memory cells MC0, MC1 to MCn are sequentially read out from the memory cells MC0, MC1 to MCn, and supplied through the bit line BL0 to the computation circuit 125. Input data are supplied, e.g., as one or more analogous input signals, to the computation circuit 125 which is configured to perform a computation, e.g., multiplication, of the one or more analogous input signals with the sequentially read out bits of the weight data. Other manners for performing CIM operations are within the scopes of various embodiments. One or more advantages described herein are achievable by the memory device 200C, in accordance with some embodiments.

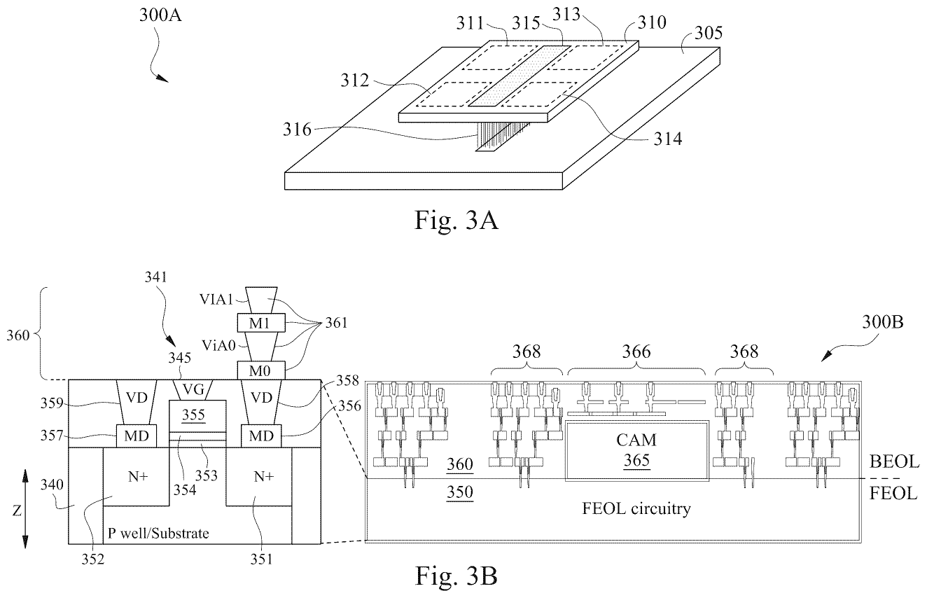

FIG. 3A is a schematic perspective view of an integrated circuit (IC) device 300A, in accordance with some embodiments.

The IC device 300A comprises an FEOL structure 305 comprising FEOL circuitry, and a BEOL structure 310 comprising at least one memory array. In some embodiments, the FEOL structure 305 corresponds to the FEOL structure 250, and/or the BEOL structure 310 corresponds to the BEOL structure 240. In the example configuration in FIG. 3A, the BEOL structure 310 comprises memory arrays 311-314. In at least one embodiment, one or more of the memory arrays 311-314 correspond to one or more of the memory arrays described with respect to FIGS. 1, 2A-2C. The BEOL structure 310 further comprises an input/output (I/O) region 315 located between the memory arrays 311, 312 on one side, and the memory arrays 313, 314 on the other side. The word lines WL, bit lines BL, BLB, and match lines ML of the memory arrays 311-314 are coupled, e.g., by interconnects (not shown) to corresponding I/O nodes or I/O pins in the I/O region 315, then through interconnects 316 to at least one memory controller (not shown) in the FEOL structure 305. In at least one embodiment, the at least one memory controller in the FEOL structure 305 corresponds to one or more of memory controllers described with respect to FIGS. 1, 2A-2C. The described number, physical arrangement and/or electrical connections of memory arrays in the BEOL structure 310 are examples. Other numbers, physical arrangements and/or electrical connections of memory arrays in the IC device 300A are within the scopes of various embodiments. One or more advantages described herein are achievable by the IC device 300A, in accordance with some embodiments.

FIG. 3B is a schematic cross-sectional view of an IC device 300B, in accordance with some embodiments. In some embodiments, the IC device 300B corresponds to the IC device 300A.

The IC device 300B comprises an FEOL structure 350 and a BEOL structure 360. In some embodiments, the FEOL structure 350 corresponds to one or more of the FEOL structures 250, 305, and/or the BEOL structure 360 corresponds to one or more of the BEOL structures 240, 310. An enlarged view of a section of the IC device 300B is illustrated on the left hand side in FIG. 3B.

As can be seen in the enlarged view in FIG. 3B, the IC device 300B comprises a substrate 340, at least one transistor 341 over the substrate 340, and the BEOL structure 360 over the transistor 341 and the substrate 340. The transistor 341 is an example of a transistor of FEOL circuitry formed over the substrate 340. The transistor 341 is sometimes referred to as an FEOL transistor. The transistor 341 serves as an example of transistors constituting various circuits in the memory device 300B including, but not limited to, word line drivers, bit line drivers, sensing circuits, pre-charging circuits, BL selection circuits, current summation circuits, a memory controller, MAC circuits, ADCs, or the like.

In some embodiments, the substrate 340 is a semiconductor substrate. N-type and P-type dopants are added to the substrate to correspondingly form N wells 351, 352, and P wells (not shown). In some embodiments, isolation structures are formed between adjacent P wells and N wells. For simplicity, several features such as P wells and isolation structures are omitted from FIG. 3B.

The transistor 341 comprises a gate and source/drains. The N wells 351, 352 configure the source/drains of the transistor 341. The gate of the transistor 341 comprises a stack of gate dielectric layers 353, 354, and a gate electrode 355. In at least one embodiment, the transistor 341 comprises a gate dielectric layer instead of multiple gate dielectrics. Example materials of the gate dielectric layer or layers include HfO2, ZrO2, or the like. Example materials of the gate electrode 355 include polysilicon, metal, or the like. The described configuration of the transistor 341 is an example. Various transistor configurations are within the scopes of various embodiments, including, but not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like.

The memory device 300B further comprises contact structures configured to electrically couple the transistor 341 to other circuitry in the memory device 300B. The contact structures comprise source/drain (metal-to-device, or MD) contacts 356, 357 correspondingly over and in electrical contact with the source/drains 351, 352. The contact structures further comprise various vias. For example, a via-to-gate (VG) via 345 is over and in electrical contact with the gate electrode 355. Via-to-device (VD) vias 358, 359 are correspondingly over and in electrical contact with the MD contacts 356, 357. The VG via 345 and/or VD vias 358, 359 are configured to couple the transistor 341 to various patterns in an M0 layer of the BEOL structure 360, as described herein.

The BEOL structure 360 comprise a plurality of metal layers M0, M1, . . . and a plurality of via layers VIA0, VIA1, . . . arranged alternatingly in a thickness direction, i.e., a Z direction, of the substrate 340. The BEOL structure 360 further comprises various interlayer dielectric (ILD) layers (not shown) in which the metal layers and via layers are embedded. The M0 layer, i.e., metal-zero (M0) layer, is the lowermost metal layer immediately over and in electrical contact with the VD and VG vias, and is schematically illustrated in the drawings with the label “M0.” The M1 layer is the metal layer immediately over the M0 layer. The BEOL structure 360 further comprises other metal layers sequentially stacked over the M1 layer. The BEOL structure 360 also comprises via layers arranged between and electrically couple successive metal layers. A via layer VIAn is arranged between and electrically couple the Mn layer and the Mn+1 layer, where n is an integer form zero and up. For example, a via-zero (VIA0) layer is the lowermost via layer which is arranged between and electrically couple the M0 layer and the M1 layer, a VIA1 layer is arranged between and electrically couple the M1 layer and the M2 layer, or the like. The metal layers and via layers of the BEOL structure 360 are configured to form interconnects that electrically couple various elements or circuits of the memory device 300B with each other, and with external circuitry. An example interconnect 361 is illustrated in FIG. 3B, and comprises at least an M0 pattern, a VIA0 via, an M1 pattern, a VIA1 via, or the like. The structure below the M0 layer and including the transistor 341 is manufactured by front-end-of-line (FEOL) processing, and corresponds to the FEOL structure 350. In contrast, the BEOL structure 360 includes the M0 layer and above and is manufactured by back-end-of-line (BEOL) processing.

In the example configuration in FIG. 3B, the BEOL structure 360 comprises a CAM memory array 365. In some embodiments, the memory array 365 corresponds to one or more of the memory arrays described with respect to FIGS. 1, 2A-2C, 3A. Word lines WL, bit lines BL, BLB, and match lines ML of the memory array 365 are coupled to a memory controller (not shown) in the FEOL circuitry of the FEOL structure 350 by interconnects in a region 366 over the memory array 365, and/or by interconnects in regions 368 around the memory array 365. In some embodiments, one or more of the word lines WL, bit lines BL, BLB, and/or match lines ML of the memory array 365 are coupled to the memory controller by interconnects (not shown) below the memory array 365 and between the memory array 365 and the FEOL structure 350, e.g., as described with respect to FIG. 3B. The described physical arrangement and/or electrical connections of the memory array 365 are examples. Other numbers, physical arrangements and/or electrical connections of memory arrays in the IC device 300B are within the scopes of various embodiments. One or more advantages described herein are achievable by the IC device 300B, in accordance with some embodiments.

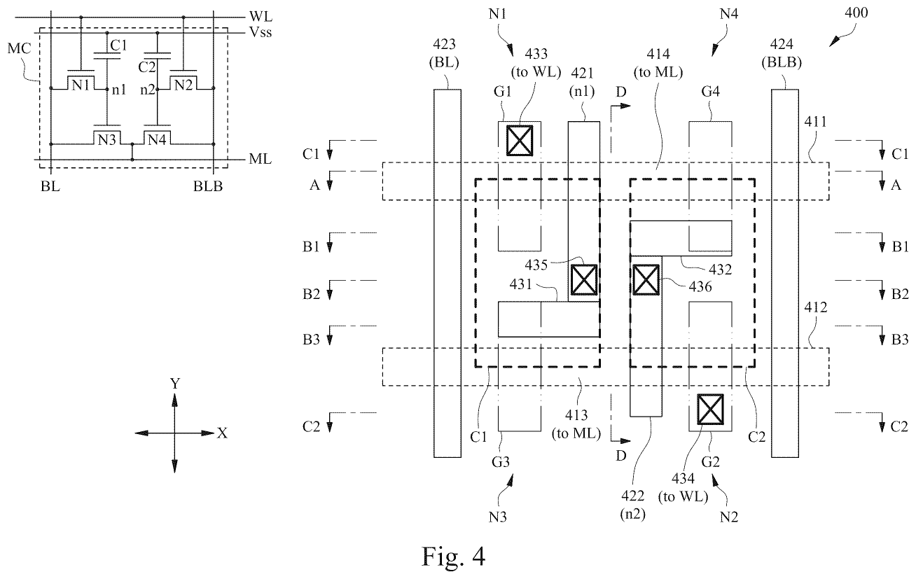

FIG. 4 is a schematic view of a layout 400 of a memory cell MC, in accordance with some embodiments. FIG. 4 also includes a schematic circuit diagram of the memory cell MC as described with respect to FIG. 2A.

An IC device with various circuit elements therein is represented in an IC layout diagram (also referred to as “IC design layout diagram,” “layout diagram,” “IC layout,” or “layout”). A layout is hierarchical and includes modules which carry out higher-level functions. The modules are often built from a combination of cells, each of which represents one or more semiconductor structures configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs. The layout 400 is an example cell, in this case a memory cell, stored in a cell library and used by an EDA tool to generate a larger layout of a memory array comprising multiple instances of the layout 400 placed in a grid arrangement.

The layout 400 comprises first and second active regions 411, 412 extending along a first direction, e.g., X direction, and spaced from each other along a second direction, e.g., Y direction, transverse to the first direction. In some embodiments, the X direction is perpendicular to the Y direction. The active regions 411, 412 correspond to active structures of a memory device or IC device manufactured in accordance with the layout 400. For simplicity, “active region” and “active structure” are used interchangeably herein. For example, active regions 411, 412 are herein referred to as active structures 411, 412.

The layout 400 further comprises first through fourth gate regions G1-G4 extending along the second direction, e.g., the Y direction. The gate regions G1-G4 correspond to gate electrodes of a memory device or IC device manufactured in accordance with the layout 400. For simplicity, “gate region” and “gate electrode” are used interchangeably herein. For example, gate regions G1-G4 are herein referred to as gate electrodes G1-G4. The gate electrodes G1, G4 are over the active structure 411 to correspondingly configure, together with the active structure 411, transistors N1, N4. The gate electrodes G2, G3 are over the active structure 412 to correspondingly configure, together with the active structure 412, transistors N2, N3. The gate electrodes G1, G3 are aligned along the Y direction. For example, a centerline of the gate electrode G1 coincides with a centerline of the gate electrode G3. Similarly, the gate electrode G2 is aligned with the gate electrode G4.

The active structure 411 is configured to configure source/drains and channels of the transistors N1, N4. Because source/drains of the transistor N1 are not directly coupled to source/drains of the transistor N4 as can be seen from the circuit diagram in FIG. 4, the active structure 411 is separated by an isolation region (not shown) into two disconnected portions, one of which overlaps the gate electrode G1 and configures the source/drains and channel of the transistor N1, whereas the other overlaps the gate electrode G4 and configures the source/drains and channel of the transistor N4. Similarly, the active structure 412 is separated by an isolation region (not shown) into two disconnected portions, one of which overlaps the gate electrode G2 and configures the source/drains and channel of the transistor N2, whereas the other overlaps the gate electrode G3 and configures the source/drains and channel of the transistor N3.

The layout 400 further comprises source/drain contacts 421-424 extending along the Y direction over at least one of the active structures 411, 412. Specifically, the source/drain contact 421 is over the active structure 411 and adjacent to the gate electrode G1. The source/drain contact 421 is configured to provide an electrical connection to a underlying first source/drain of the transistor N1. The source/drain contact 423 is over the active structure 411 and adjacent to the gate electrode G1. The source/drain contact 423 is configured to provide an electrical connection to a underlying second source/drain of the transistor N1. The source/drain contact 423 further extends continuously along the Y direction to be over the active structure 412 and adjacent to the gate electrode G3. The source/drain contact 423 is also configured to provide an electrical connection to a underlying source/drain of the transistor N3. In the example configuration in FIG. 4, the source/drain contact 423 corresponds to the bit line BL. The source/drain contact 422 is over the active structure 412 and adjacent to the gate electrode G2. The source/drain contact 422 is configured to provide an electrical connection to a underlying first source/drain of the transistor N2. The source/drain contact 424 is over the active structure 412 and adjacent to the gate electrode G2. The source/drain contact 424 is configured to provide an electrical connection to a underlying second source/drain of the transistor N2. The source/drain contact 424 further extends continuously along the Y direction to be over the active structure 411 and adjacent to the gate electrode G4. The source/drain contact 424 is also configured to provide an electrical connection to a underlying source/drain of the transistor N4. In the example configuration in FIG. 4, the source/drain contact 424 corresponds to the bit line BLB. In some embodiments, at least one of the source/drain contacts 423, 424 includes two physically disconnected source/drain contacts, which are over and in direct electrical contact with the corresponding underlying source/drains, and which are electrically coupled by interconnects to the corresponding bit line BL or bit line BLB at a metal layer above or below the memory cell MC.

The layout 400 further comprises transverse interconnects 431, 432 extending along the X direction. The transverse interconnect 431 is configured to electrically couple the source/drain contact 421, and the underlying source/drain of the transistor N1, to the gate electrode G3. A first interconnect structure comprising the source/drain contact 421 and transverse interconnect 431 corresponds to the node n1. The transverse interconnect 432 is configured to electrically couple the source/drain contact 422, and the underlying source/drain of the transistor N2, to the gate electrode G4. A second interconnect structure comprising the source/drain contact 422 and transverse interconnect 432 corresponds to the node n2. In the example configuration in FIG. 4, the first and second interconnect structures are L-shaped.

The layout 400 further comprises vias 433-436. The vias 433, 434 are correspondingly over, and configured to provide electrical connections from the gate electrodes G1, G2 to a word line WL (not shown). The vias 435, 436 are correspondingly over, and configured to provide electrical connections to the source/drain contacts 421, 422. In some embodiments, at least one of the vias 435, 436 is over, or overlaps, the corresponding transverse interconnect 431 or transverse interconnect 432.

A source/drain 413 of the transistor N3 and a source/drain 414 of the transistor N4 are configured to be electrically coupled to a match line ML. For example, the layout 400 further comprises a source/drain contact (not shown) which is similar to the source/drain contact 421, is over the source/drain 414, and is aligned along the Y direction with the source/drain contact 422 without touching the source/drain contact 422 and the transverse interconnect 432. The layout 400 further comprises a via (not shown) which is similar to the via 433 and is over an upper end (in FIG. 4) of the source/drain contact over the source/drain 414. The layout 400 further comprises a source/drain contact (not shown) which is similar to the source/drain contact 422, is over the source/drain 413, and is aligned along the Y direction with the source/drain contact 421 without touching the source/drain contact 421 and the transverse interconnect 431. The layout 400 further comprises a via (not shown) which is similar to the via 434 and is over a lower end (in FIG. 4) of the source/drain contact over the source/drain 413.

The layout 400 further comprises capacitors C1, C2 correspondingly over, and electrically coupled to, the vias 435, 436. In the example configuration in FIG. 4, each of the capacitors C1, C2, is illustrated by a rectangular boundary of a bottom electrode of the capacitor C1, C2 that is electrically coupled to the corresponding via 435, 436. The capacitor C1 overlaps the via 435, source/drain contact 421, transverse interconnect 431, gate electrode G1, gate electrode G3, active structures 411, 412. The capacitor C2 overlaps the via 436, source/drain contact 422, transverse interconnect 432, gate electrode G2, gate electrode G4, active structures 411, 412. The described shape and physical arrangement of the capacitors C1, C2, are examples. Other capacitor configurations and/or arrangements are within the scopes of various embodiments.

The layout 400 further comprises a ground, or VSS, power rail (not shown), and vias or interconnects (not shown) electrically coupling a top electrode of each of the capacitors C1, C2, to the VSS power rail. The described layout is an example. Other layouts for one or more memory cells as described herein are within the scopes of various embodiments. One or more advantages described herein are achievable by memory devices and/or IC devices including one or more memory arrays of memory cells corresponding to the layout 400, in accordance with some embodiments.

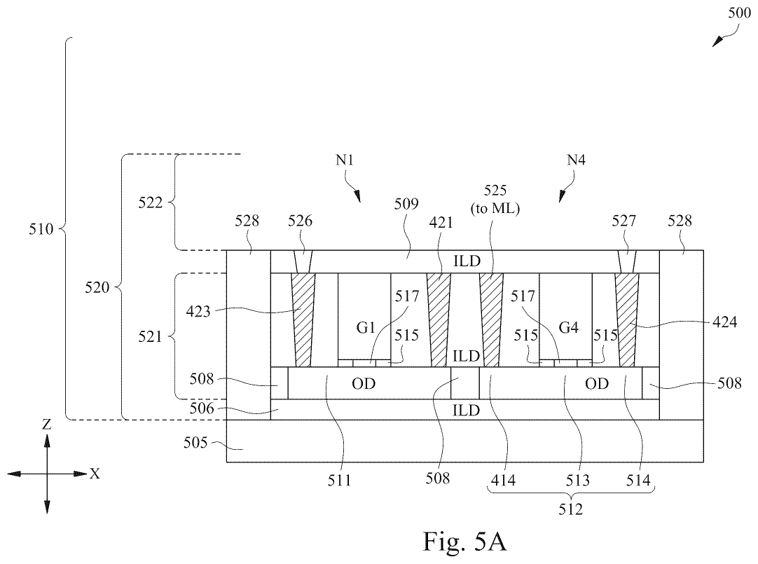

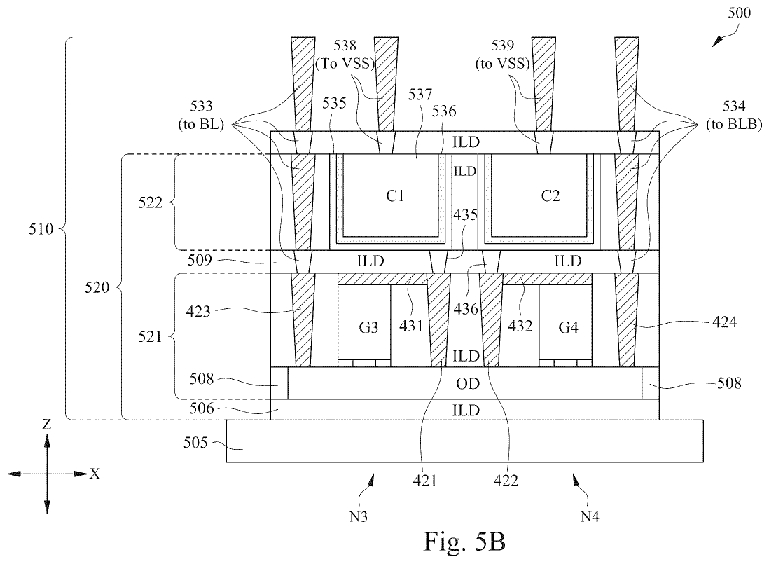

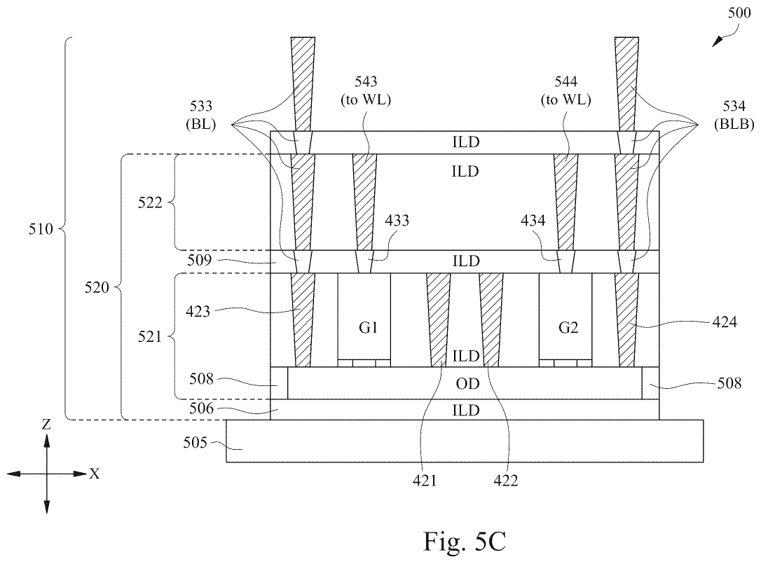

FIG. 4 further includes various cross-section lines corresponding to various cross-sectional views described with respect to FIGS. 5A-5D. For example, a cross-section line A-A in FIG. 4 corresponds to a cross-sectional view in FIG. 5A, cross-section lines B1-B1, B2-B2, B3-B3 in FIG. 4 correspond to a cross-sectional view in FIG. 5B, cross-section lines C1-C1, C2-C2 in FIG. 4 correspond to a cross-sectional view in FIG. 5C, and a cross-section line D-D in FIG. 4 correspond to a cross-sectional view in FIG. 5D. Components in FIGS. 5A-5D having corresponding components in FIG. 4 are designated by the same reference numerals as in FIG. 4.

FIG. 5A is a schematic cross-sectional view of a region of an IC device 500, in accordance with some embodiments. The region of the IC device 500 corresponds to the layout 400, and the cross-sectional view in FIG. 5A corresponds to the cross-section line A-A in FIG. 4. In some embodiments, the IC device 500 corresponds to one or more of the memory devices and/or IC devices described with respect to FIGS. 1, 2A-2C, 3A-3B.

The IC device 500 comprises an FEOL structure 505, and a BEOL structure 510 over the FEOL structure 505 along a thickness direction of the IC device 500, e.g., along the Z direction. In some embodiments, the FEOL structure 505 corresponds to one or more of the FEOL structures 250, 305, 350, and/or the BEOL structure 510 corresponds to one or more of the BEOL structures 240, 310, 360. The FEOL structure 505 comprises FEOL circuitry (not shown) having FEOL transistors, as described herein.

The BEOL structure 510 comprises a memory array 520 of a plurality of memory cells arranged in a grid as described herein. The memory cells of the memory array 520 correspond to the memory cell MC and layout 400 described with respect to FIG. 4. A memory cell of the memory array 520 is illustrated in FIG. 5A, as an example. The BEOL structure 510 further comprises other conductive features, such as interconnects 528, and various interlayer dielectric (ILD) layers in which elements of the BEOL structure 510 are embedded. Examples of interconnects 528 include, but are not limited to, the interconnect 361 and various interconnects in regions 368 around the memory array 365 described with respect to FIG. 3B, or the like. For simplicity, not all ILD layers are separately numbered in the drawings, and the ILD layers are commonly designated with a label “ILD”.

The memory array 520 is over the FEOL structure 505 with an ILD layer 506 in between. In some embodiments, the ILD layer 506 contains therein one or more interconnects (not shown) below the memory array 520 and configured to electrically couple circuit elements of the memory array 520 with each other, and/or with the FEOL circuitry in the FEOL structure 505, and/or with external circuitry.

The memory array 520 comprises a BEOL transistor layer 521 over the ILD layer 506, and a BEOL capacitor layer 522 over the BEOL transistor layer 521. The BEOL transistor layer 521 includes BEOL transistors of memory cells of the memory array 520. For example, the transistors N1, N4 in the BEOL transistor layer 521 are illustrated in FIG. 5A. The BEOL capacitor layer 522 comprises BEOL capacitors of memory cells of the memory array 520. Such BEOL capacitors are not visible and not illustrated in the cross-sectional view in FIG. 5A. Example BEOL capacitors of the BEOL capacitor layer 522 are described with respect to FIG. 5B.

The BEOL transistor layer 521 comprises active structures over the ILD layer 506. For example, the memory cell in FIG. 5A comprises active structures 511, 512 which correspond to the disconnected portions of the active structure 411 as described with respect to FIG. 4. The active structures 511, 512 are separated from each other and from active structures of adjacent memory cells by various isolation structures (ISO) 508. Each of the active structures 511, 512 configures source/drains and a channel of a corresponding transistor. For example, the active structure 512 configures, for the transistor N4, the source/drain 414, another source/drain 514, and a channel 513 between the source/drains 414, 514. In the drawings, active structures are commonly designated with a label “OD”.

The BEOL transistor layer 521 further comprises gate dielectric layers and spacers over the channels in the active structures. For example, the transistor N4 comprises a gate dielectric layer 517 over the channel 513, and spacers 515 on opposite sides of, or surrounding, the gate dielectric layer 517.

The BEOL transistor layer 521 further comprises gate electrodes over the gate dielectric layers and spacers. For example, the transistor N4 comprises the gate electrode G4 over the gate dielectric layer 517 and spacers 515. The transistor N1 is configured similarly to the transistor N4.

The BEOL transistor layer 521 further comprises source/drain contacts coupled to corresponding source/drains of the transistors. For example, source/drain contacts 423, 421, 525, 424 are illustrated in FIG. 5A as being over and in electrical contact with the corresponding source/drains of the transistors N1, N4. The source/drain contact 525 is over the source/drain 414 and is configured to couple the source/drain 414 to a corresponding match line ML. The BEOL transistor layer 521 further comprises an ILD layer surrounding the electrodes, gate dielectric layers, spacers, and source/drain contacts.

The BEOL structure 510 comprises an ILD layer 509 over the BEOL transistor layer 521. The ILD layer 509 contains therein various vias coupled to the gate electrodes and source/drain contacts in the BEOL transistor layer 521. For example, vias 526, 527 are illustrated in FIG. 5A as being correspondingly over and in electrical contact with the source/drain contacts 423, 424.

FIG. 5B is a schematic cross-sectional view of the region of the IC device 500, in accordance with some embodiments. The cross-sectional view in FIG. 5B is a combination of cross-sectional views along the cross-section lines B1-B1, B2-B2, B3-B3 in FIG. 4. Specifically, the cross-sectional view in FIG. 5B includes a left portion up to and including the source/drain contact 421, a right portion up to and including the source/drain contact 422, and a middle portion between and including the source/drain contacts 421, 422. In the cross-sectional view of FIG. 5B, the left portion corresponds to the cross-section line B3-B3, the middle section corresponds to the cross-section line B2-B2, and the right portion corresponds to the cross-section line B1-B1.

As can be seen in FIG. 5B, the BEOL transistor layer 521 comprises a transverse interconnect 431 extending along the X direction between, and coupling, upper portions of the source/drain contact 421 and the gate electrode G3. In some embodiments, the upper portion of the gate electrode G3 is partially removed during manufacture, and the transverse interconnect 431 is formed in a space left by the partial removal of the upper portion of the gate electrode G3. In at least one embodiment, the source/drain contact 421 and transverse interconnect 431 are manufactured as an integral conductive structure, e.g., in a process similar to a dual-damascene fabrication process.

The BEOL transistor layer 521 further comprises a transverse interconnect 432 extending along the X direction between, and coupling, upper portions of the source/drain contact 422 and the gate electrode G4. In some embodiments, the upper portion of the gate electrode G4 is partially removed during manufacture, and the transverse interconnect 432 is formed in a space left by the partial removal of the upper portion of the gate electrode G4. In at least one embodiment, the source/drain contact 422 and transverse interconnect 432 are manufactured as an integral conductive structure, e.g., in a process similar to a dual-damascene fabrication process.

The ILD layer 509 over the BEOL transistor layer 521 further comprises vias 435, 436, correspondingly over, and coupled to the source/drain contacts 421, 422.

The BEOL capacitor layer 522 is over the ILD layer 509. Each BEOL capacitor in the BEOL capacitor layer 522 is coupled to a corresponding via in the 509. In the example configuration in FIG. 5B, the BEOL capacitor layer 522 comprises capacitors C1, C2, correspondingly over and coupled to the vias 435, 436. The capacitor C1 comprises a bottom electrode 535 over and coupled to the via 435, a dielectric layer 536 over the bottom electrode 535, and a top electrode 537 over the dielectric layer 536. In at least one embodiment, a boundary of the bottom electrode 535 in plan view corresponds to the boundary of capacitor C1 as described with respect to FIG. 4. The bottom electrode 535 and dielectric layer 536 have a U shape. This is an example, and other shapes and/or configurations for capacitors are within the scopes of various embodiments. For example, in one or more embodiments, the bottom electrode 535, dielectric layer 536 and top electrode 537 are all planar in shape. The capacitor C2 is configured and electrically coupled in a manner similar to the capacitor C1.

The BEOL structure 510 comprises various interconnects around and over the capacitors in the BEOL capacitor layer 522. For example, interconnects 533, 534 each comprising several metal patterns and vias and correspondingly coupled to the source/drain contacts 423, 424 provide electrical connections from the memory cell correspondingly to the bit line BL and bit line BLB. For another example, interconnects 538, 539 each comprising at least one metal pattern and at least one via provide electrical connections from the top electrodes of the capacitors C1, C2 to VSS, e.g., to a VSS power rail.

In the example configuration of the memory array 520 in FIG. 5B, the BEOL capacitor layer 522 is over the BEOL transistor layer 521 along the Z direction. In at least one embodiment, the BEOL capacitor layer 522 is under, rather than over, the BEOL transistor layer 521 along the Z direction. These are examples of a stacked arrangement in which the transistors in the BEOL transistor layer 521 are at a first level along the thickness direction, i.e., Z direction, whereas the capacitors in the BEOL capacitor layer 522 are at a second level different from the first level. This stacked arrangement of the transistors and capacitors along the Z direction contributes to a further reduction in the area occupied by the memory array 520, in one or more embodiments.

FIG. 5C is a schematic cross-sectional view of the region of the IC device 500, in accordance with some embodiments. The cross-sectional view in FIG. 5C is a combination of cross-sectional views along the cross-section lines C1-C1, C2-C2 in FIG. 4. Specifically, the cross-sectional view in FIG. 5C includes a left portion up to and including the source/drain contact 421, and a right portion up to and including the source/drain contact 422. In the cross-sectional view of FIG. 5C, the left portion corresponds to the cross-section line C1-C1, and the right portion corresponds to the cross-section line C2-C2.

As can be seen in FIG. 5C, the ILD layer 509 further contains therein the vias 433, 434 correspondingly over and coupled to the gate electrodes G1, G2. The BEOL structure 510 further comprises, adjacent to the capacitors in the BEOL capacitor layer 522, interconnects 543, 544 correspondingly over and coupled to the vias 433, 434 to provide electrical connections from the gate electrodes G1, G2 to the word line WL.

FIG. 5D is a schematic cross-sectional view of the region of the IC device 500, in accordance with some embodiments. The cross-sectional view in FIG. 5D corresponds to the cross-section line D-D in FIG. 4. Unlike the cross-section lines A-A, B1-B1, B2-B2, B3-B3, C1-C1, C2-C2 which extend along the X direction, the cross-section line D-D extends along the Y direction.

As can be seen in FIG. 5D, the BEOL transistor layer 521 comprises active structures 551-554 separated from each other by various isolation structures 508. Each of the active structures 551-554 configures source/drains and a channel of a transistor in a memory cell of the memory array 520. A source/drain contact 555 is over and couples the adjacent active structures 551, 552. A source/drain contact 556 is over and couples the adjacent active structures 553, 554. Other features of the memory array 520 are omitted for simplicity. One or more advantages described herein are achievable by the IC device 500, in accordance with some embodiments.

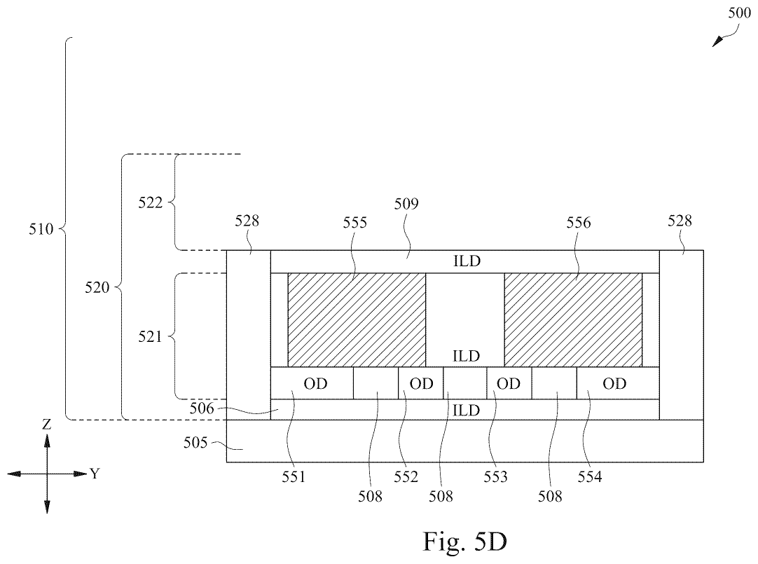

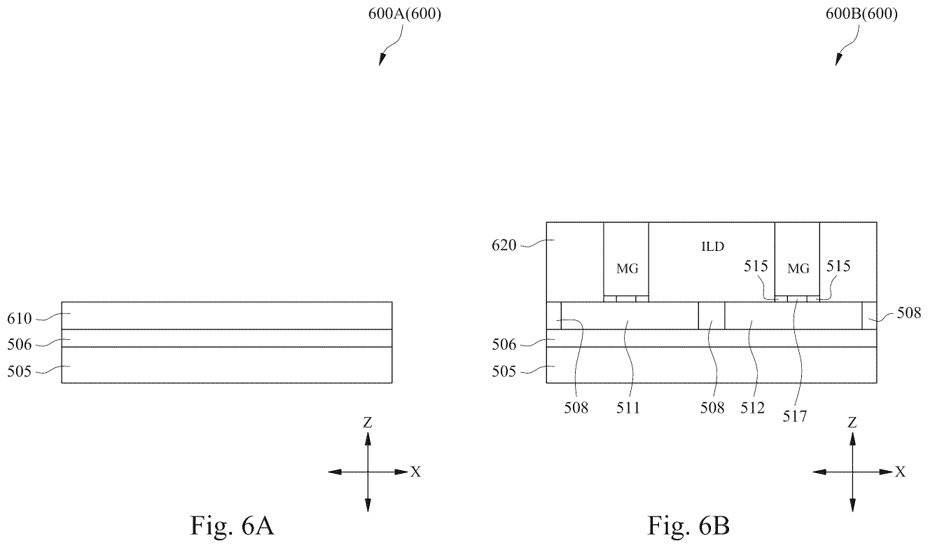

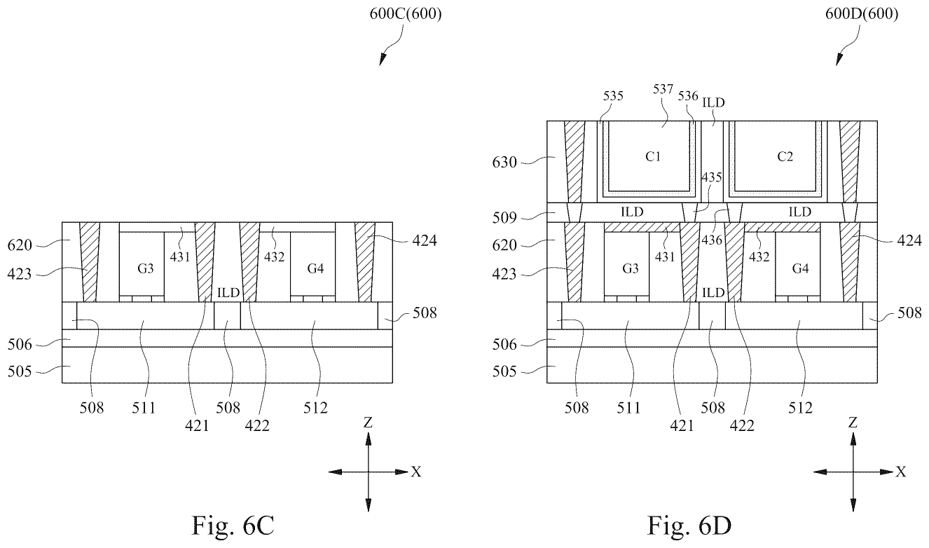

FIGS. 6A-6D are schematic cross-sectional views of an IC device 600 at various stages during a manufacturing process, in accordance with some embodiments. In some embodiments, the IC device 600 corresponds to the IC device 500. Components in FIGS. 6A-6D having corresponding components in FIGS. 5A-5D are designated by the same reference numerals as in FIGS. 5A-5D.

In FIG. 6A, an FEOL processing is performed to obtain an FEOL structure 505 comprising FEOL circuitry over a substrate, e.g., as described with respect to FIG. 3B. Subsequent operations and/or features formed on the FEOL structure 505 are sometimes referred to as BEOL processing. For example, the BEOL processing starts with a deposition of an ILD layer 506 over the FEOL structure 505. An active layer 610 is next deposited over the ILD layer 506. In some embodiments, the active layer 610 comprises a semiconductor material, such as amorphous silicon. In at least one embodiment, the active layer 610 comprises an oxide layer, e.g., InGaZnO4 (IGZO). Other materials of the active layer 610 are within the scopes of various embodiments. In some embodiments, an annealing process is performed on the active layer 610. A resulting structure 600A is obtained.

In FIG. 6B, isolation structures 508 are formed to separate the active layer 610 of the structure 600A into discrete active structures, e.g., active structures 511, 512. In an example, the active layer 610 is patterned by a lithography process and an etching process, and an insulation material is filled in the spaces left after patterning the active layer 610, to obtain the isolation structures 508. In some embodiments, the described annealing process is performed after forming the isolation structures 508.

In some embodiments, various depositing and patterning processes are performed to obtain gate dielectric layers 517, spacers 515 around the gate dielectric layers 517, and gate electrodes (labelled as “MG” in the drawings) over the corresponding gate dielectric layers 517 and spacers 515. In some embodiments, exposed portions of the active structures not covered by the gate electrodes MG are subject to an ion implantation process and/or an annealing process to form source/drains therein. Example materials of the gate dielectric layers 517 include, but are not limited to, oxide, nitride, oxynitride, or high-k dielectric materials, such as Al2O3, HfO2, ZrO2, HfOxNy, ZrOxNy, HfSixOy, ZrSixOy, HfSixOyNz, ZrSixOyNz, TiO2, Ta2O5, La2O3, CeO2, Bi4Si2O12, WO3, Y2O3, LaALO3, Bal-xSrxTiO3, PbTiO3, BaTiO3 (BTO), SrTiO3 (STO), BaSrTiO3 (BST), PbZrO3, lead-strontium-titanate (PST), lead-zinc-niobate (PZN), lead-zirconate-titanate (PZT), lead-magnesium-niobium (PMN), yttria-stabilized zirconia (YSZ), ZnO/Ag/ZnO (ZAZ), a combination thereof, or the like. Example materials of the gate electrodes MG include doped polysilicon, Co, Ru, Al, Ag, Au, W, Ni, Ti, Cu, Mn, Pd, Re, Ir, Pt, Zr, alloys thereof, combinations thereof, or the like. In some embodiments, the described materials of the gate dielectric layers 517 and gate electrodes MG are usable to form gate dielectric layers and gate electrodes for FEOL transistors in the FEOL structure 505. In at least one embodiment, FEOL transistors are different from BEOL transistors in the channel material, e.g., the channel material in FEOL transistors comprises Si, whereas the channel material in BEOL transistors comprises an oxide layer. An ILD layer 620 is deposited around the gate electrodes MG. A resulting structure 600B is obtained.

In FIG. 6C, a patterning process is performed on the ILD layer 620 to form spaces into which a conductive material will be subsequently deposited to form source/drain contacts. In at least one embodiment, upper portions of gate electrodes G3, G4 (which are examples of gate electrodes MG) are partially removed during this patterning process. A conductive material, e.g., a metal, TiN, or the like, is deposited into the spaces left after the patterning process, resulting in various source/drain contacts 421-424 and transverse interconnects 431, 432. A resulting structure 600C is obtained.

In FIG. 6D, an ILD layer 509 is deposited over the structure 600C. Various vias are formed in the ILD layer 509. For example, vias 435, 436 are formed in the ILD layer 509 to be over and coupled to the source/drain contacts 421, 422. An ILD layer 630 is deposited over the ILD layer 509 and the vias formed therein. A patterning process is performed on the ILD layer 630 to form spaces into which a conductive material will be subsequently deposited to form interconnects. The patterning process also form openings over the vias 435, 436 to expose these vias. The openings have a size and a shape corresponding to those of a capacitor to be formed therein. A first conductive material, a dielectric material, and a second conductive material are sequentially filled in each of the openings, to sequentially form the bottom electrode 535, dielectric layer 536 and top electrode 537. For example, the first conductive material is deposited to line the side walls and bottom wall of the opening, and is configured to form a bottom electrode. The dielectric material is then deposited over the first conductive material, and also to line the side walls and bottom wall of the opening, to obtain a dielectric layer for the capacitor being formed. The second conductive material is then deposited to fill a remainder of the opening. A resulting structure 600D is obtained. In some embodiments, further depositing and patterning processes are performed to form, over the capacitors, further interconnects, and one or more of word lines, pairs of bit lines, match lines, or the like. The process described with respect to FIGS. 6A-6D is BEOL compatible. One or more advantages described herein are achievable by the IC device 600 manufactured by the described manufacturing process, in accordance with some embodiments.

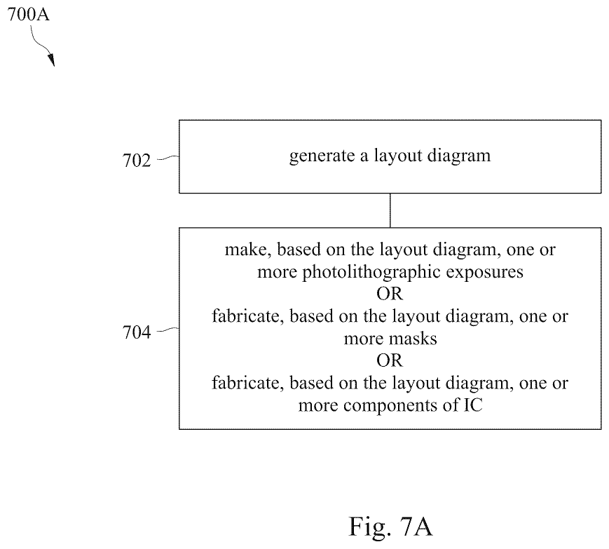

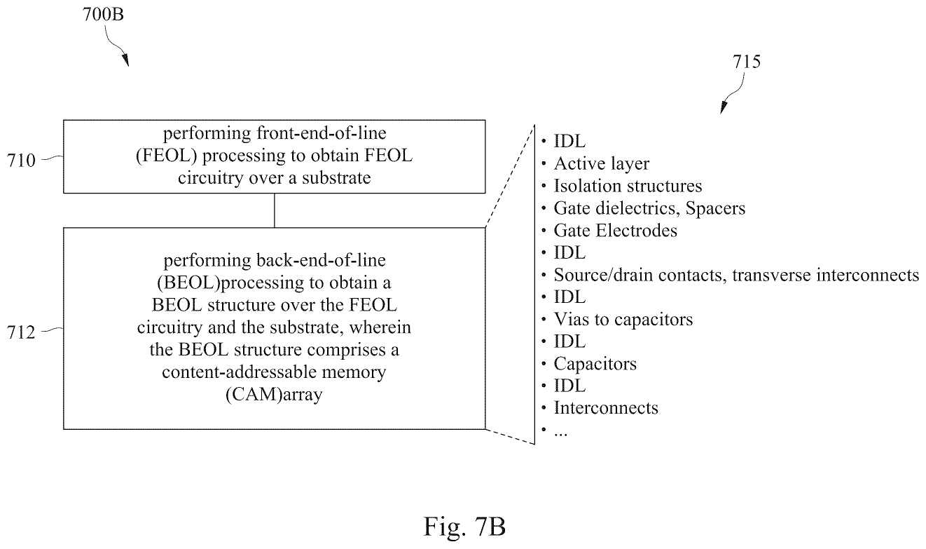

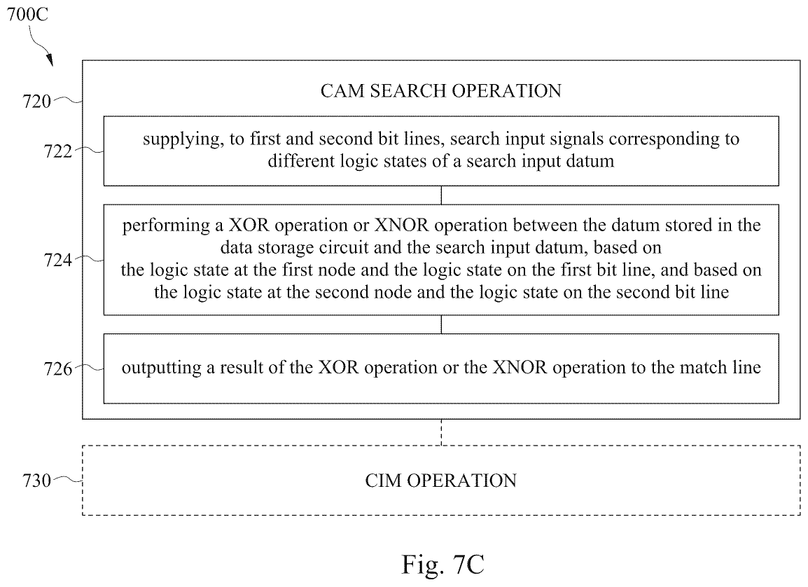

FIG. 7A is a flowchart of a method 700A of designing and/or manufacturing an IC device, in accordance with some embodiments. In some embodiments, the method 700A is usable for designing and/or manufacturing one or more IC devices as described herein. The method 700A is implementable, for example, using an EDA system discussed below, and/or a manufacturing system discussed below, in accordance with some embodiments.

At operation 702, a layout diagram is generated which, among other things, includes one or more of layouts for various circuits as disclosed herein, or the like. Operation 702 is implementable, for example, using an EDA system discussed below, in accordance with some embodiments. Examples of layout diagrams obtained at operation 702 comprise one or more layout diagrams described herein.

At operation 704, based on the layout diagram, at least one of (A) one or more photolithographic exposures are made or (B) one or more semiconductor masks are fabricated or (C) one or more components in a layer of an IC device are fabricated. Operation 704 is implementable, for example, using a manufacturing system discussed below, in accordance with some embodiments. Examples of IC devices obtained at operation 704 comprise one or more IC devices described herein. In some embodiments, operation 704 is omitted.

FIG. 7B is a flowchart of a method 700B, in accordance with some embodiments. In some embodiments, the method 700B is performed to manufacture a memory device or an IC device as described herein, and/or in accordance with the layout 400. The method 700B comprises operations 710, 712.

At operation 710, front-end-of-line (FEOL) processing is performed to obtain FEOL circuitry over a substrate. For example, as described with respect to FIG. 3B, FEOL processing is performed to obtain, over a substrate 340, an FEOL structure 350 under the M0 layer. The FEOL structure 350 comprises FEOL circuitry, represented by a transistor 341. In some embodiments, the FEOL circuitry comprises a memory controller, as described herein.

At operation 712, back-end-of-line (BEOL) processing is performed to obtain a BEOL structure over the FEOL circuitry and the substrate. The BEOL structure comprises a content-addressable memory (CAM) array. For example, as described with respect to FIGS. 3B, 5A-5D, 6A-6D, BEOL processing is performed to obtain a BEOL structure 360, 510 over the FEOL circuitry and the substrate. In some embodiments, the CAM array corresponds to one or more memory arrays described herein. In at least one embodiment, the CAM array comprises a 4T2C memory array.

An example sequence 715 of manufacturing processes in operation 712 is illustrated in FIG. 7B. In the example sequence 715, an ILD layer 506 is formed over an FEOL structure 505, and an active layer 610 is formed over the ILD layer 506, as described with respect to FIG. 6A. Isolation structures 508 are formed to separate the active layer 610 into discrete active structures 511, 512, gate dielectric layers 517 and spacers 515 are formed over the active structures, gate electrodes MG are formed over the corresponding gate dielectric layers 517, and an ILD layer 620 is formed around the gate electrodes MG, as described with respect to FIG. 6B. Source/drain contacts 421-424 and transverse interconnects 431, 432 are formed in the ILD layer 620, as described with respect to FIG. 6C. An ILD layer 509 is deposited over the ILD layer 620, vias 435, 436 for capacitors are formed in the ILD layer 509, an ILD layer 630 is formed over the ILD layer 509 with the vias 435, 436, and capacitors C1, C2, are formed in the ILD layer 630, as described with respect to FIG. 6D. As a result, a BEOL CAM array is obtained. In some embodiments, a process including deposition of a further ILD layer and formation of various interconnects in the further ILD layer is repeatedly performed to obtain various word lines, pairs of bit lines and match lines, and to couple the word lines, pairs of bit lines and match lines to corresponding memory cells in the CAM array. One or more advantages described herein are achievable by memory devices and/or IC devices manufactured by the method 700B, in accordance with some embodiments.

FIG. 7C is a flowchart of a method 700C, in accordance with some embodiments. In some embodiments, the method 700C is performed in or by one or more of the memory devices or IC devices described herein. The method 700C comprises a CAM search operation 720, and a CIM operation 730. In some embodiments, the CIM operation 730 is omitted. The CAM search operation 720 comprises operations 722, 724, 726.

At operation 722, search input signals corresponding to different logic states of a search input datum are supplied to first and second bit lines. For example, as described with respect to FIG. 2A, when the search input datum (or search bit) is logic “1”, logic “1” is supplied to the bit line BL and logic “0” is supplied to the bit line BLB. When the search input datum is logic “0”, logic “0” is supplied to the bit line BL and logic “1” is supplied to the bit line BLB.

At operation 724, at least one memory cell coupled to the first and second bit lines performs an XOR operation or XNOR operation between the datum stored in a data storage circuit of the memory cell and the search input datum. The XOR operation or XNOR operation is based on a logic state at a first node of the data storage circuit and the logic state on the first bit line, and based on a logic state at a second node of the data storage circuit and the logic state on the second bit line. For example, as described with respect to FIG. 2A, an XNOR operation is performed in the memory cell for various situations with different logic states of the search bit on the bit lines BL, BLB and a stored bit stored in the data storage circuit of the memory cell.

At operation 726, a result of the XOR operation or the XNOR operation is output to a match line coupled to the at least one memory cell. For example, as described with respect to the truth table 230 in FIG. 2A, when the search bit and stored bit match, the match line ML has logic “1”, and when the search bit and stored bit do not match, the match line ML has logic “0”. In some embodiments, by configuring a BEOL memory array to perform search operations, it is possible to quickly obtain the result, without overloading a processor, while reducing standby leakage and/or power consumption. One or more further advantages are achievable by the method 700C, in accordance with some embodiments.

At operation 730, a CIM operation is performed. For example, as described with respect to FIG. 2A, input voltages corresponding to input data are supplied, via corresponding word lines WL0-WLn, to the memory cells coupled to a bit line BL. In response to the input voltages, each of the memory cells coupled to the bit line BL is caused to output a current I0, I1 to In. The currents output by the memory cells are collected as a bit line current IBL. Based on a current value of the bit line current IBL, the memory controller is configured to determine a result of the CIM operation. One or more further advantages are achievable by the method 700C, in accordance with some embodiments.

The described methods and algorithms include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

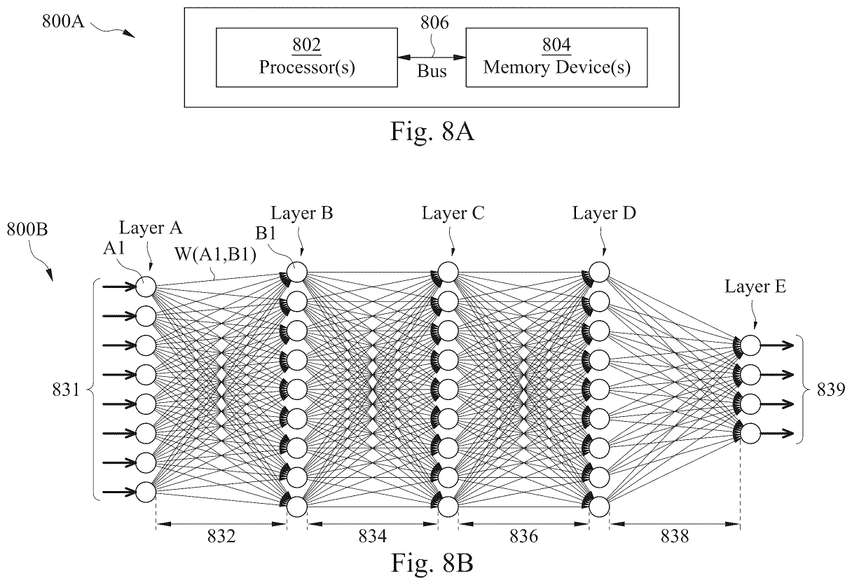

FIG. 8A is a schematic diagram of an integrated circuit (IC) device 800A, in accordance with some embodiments.

The IC device 800A comprises one or more hardware processors 802, one or more memory devices 804 coupled to the processors 802 by one or more buses 806. In some embodiments, the IC device 800A comprises one or more further circuits including, but not limited to, cellular transceiver, global positioning system (GPS) receiver, network interface circuitry for one or more of Wi-Fi, USB, Bluetooth, or the like. Examples of the processors 802 include, but are not limited to, a central processing unit (CPU), a multi-core CPU, a neural processing unit (NPU), a graphics processing unit (GPU), a digital signal processor (DSP), a field-programmable gate array (FPGA), an application-specific integrated circuit (ASIC), other programmable logic devices, a multimedia processor, an image signal processors (ISP), or the like. Examples of the memory devices 804 include one or more memory devices described herein. In at least one embodiment, each of the processors 802 is coupled to a corresponding memory device among the memory devices 804.

In some embodiments, one or more of the memory devices 804 are configured to perform one or more CAM search operations, CIM operations and/or CIM functions, as described herein. As a result, it is possible in one or more embodiments to reduce the computing workload of the corresponding processor 802, reduce memory access time, and/or improve performance. In at least one embodiment, the IC device 800A is a system-on-a-chip (SOC). In at least one embodiment, one or more advantages described herein are achievable by the IC device 800A.

FIG. 8B is a schematic diagram of a neural network 800B, in accordance with some embodiments.

The neural network 800B comprises a plurality of layers A-E each comprising a plurality of nodes (or neurons). The nodes in successive layers of the neural network 800B are connected with each other by a matrix or array of connections. For example, the nodes in layers A and B are connected with each other by connections in a matrix 832, the nodes in layers B and C are connected with each other by connections in a matrix 834, the nodes in layers C and D are connected with each other by connections in a matrix 836, and the nodes in layers D and E are connected with each other by connections in a matrix 838. Layer A is an input layer configured to receive input data 831. The input data 831 propagate through the neural network 800B, from one layer to the next layer via the corresponding matrix of connections between the layers. As the data propagate through the neural network 800B, the data undergo one or more computations, and are output as output data 839 from layer E which is an output layer of the neural network 800B. Layers B, C, D between input layer A and output layer E are sometimes referred to as hidden or intermediate layers. The number of layers, number of matrices of connections, and number of nodes in each layer in FIG. 8B are examples. Other configurations are within the scopes of various embodiments. For example, in at least one embodiment, the neural network 800B includes no hidden layer, and has an input layer connected by one matrix of connections to an output layer. In one or more embodiments, the neural network 800B has one, two, or more than three hidden layers.

In some embodiments, at least one of the matrices 832, 834, 836, 838 is implemented by a memory array or a memory device as described herein. Specifically, in the matrix 832, a connection between a node in layer A and another node in layer B has a corresponding weight. For example, a connection between node A1 and node B1 has a weight W (A1, B1) which corresponds to weight data stored, e.g., in one or more memory arrays or memory devices as described herein. In some embodiments, the weight data in one or more of the memory arrays or memory devices are updated, e.g., by a processor and/or through a memory controller, as machine learning is performed using the neural network 800B. One or more advantages described herein are achievable in the neural network 800B implemented in whole or in part by one or more memory arrays or memory devices in accordance with some embodiments.

In some embodiments, at least one method(s) discussed above is performed in whole or in part by at least one EDA system. In some embodiments, an EDA system is usable as part of a design house of an IC manufacturing system discussed below.

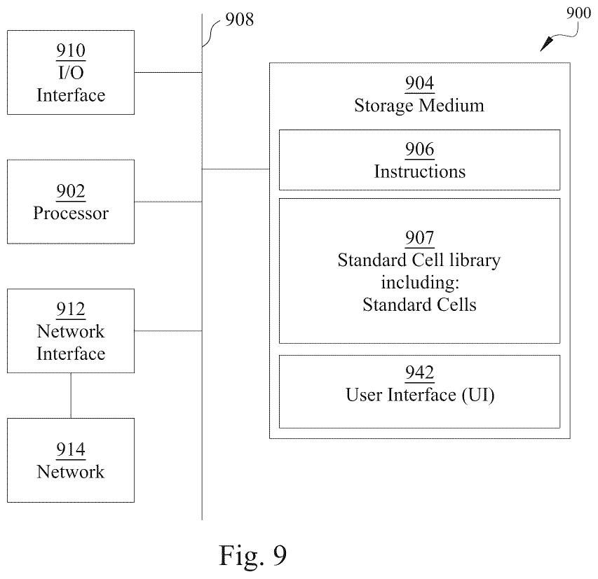

FIG. 9 is a block diagram of an electronic design automation (EDA) system 900 in accordance with some embodiments.

In some embodiments, EDA system 900 includes an APR system. Methods described herein of designing layout diagrams represent wire routing arrangements, in accordance with one or more embodiments, are implementable, for example, using EDA system 900, in accordance with some embodiments.

In some embodiments, EDA system 900 is a general purpose computing device including a hardware processor 902 and a non-transitory, computer-readable storage medium 904. Storage medium 904, amongst other things, is encoded with, i.e., stores, computer program code 906, i.e., a set of executable instructions. Execution of instructions 906 by hardware processor 902 represents (at least in part) an EDA tool which implements a portion or all of the methods described herein in accordance with one or more embodiments (hereinafter, the noted processes and/or methods).

Processor 902 is electrically coupled to computer-readable storage medium 904 via a bus 908. Processor 902 is also electrically coupled to an I/O interface 910 by bus 908. A network interface 912 is also electrically connected to processor 902 via bus 908. Network interface 912 is connected to a network 914, so that processor 902 and computer-readable storage medium 904 are capable of connecting to external elements via network 914. Processor 902 is configured to execute computer program code 906 encoded in computer-readable storage medium 904 in order to cause system 900 to be usable for performing a portion or all of the noted processes and/or methods. In one or more embodiments, processor 902 is a central processing unit (CPU), a multi-processor, a distributed processing system, an application specific integrated circuit (ASIC), and/or a suitable processing unit.

In one or more embodiments, computer-readable storage medium 904 is an electronic, magnetic, optical, electromagnetic, infrared, and/or a semiconductor system (or apparatus or device). For example, computer-readable storage medium 904 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 904 includes a compact disk-read only memory (CD-ROM), a compact disk-read/write (CD-R/W), and/or a digital video disc (DVD).

In one or more embodiments, storage medium 904 stores computer program code 906 configured to cause system 900 (where such execution represents (at least in part) the EDA tool) to be usable for performing a portion or all of the noted processes and/or methods. In one or more embodiments, storage medium 904 also stores information which facilitates performing a portion or all of the noted processes and/or methods. In one or more embodiments, storage medium 904 stores library 907 of standard cells including such standard cells as disclosed herein.

EDA system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 902.

EDA system 900 also includes network interface 912 coupled to processor 902. Network interface 912 allows system 900 to communicate with network 914, to which one or more other computer systems are connected. Network interface 912 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 900.

System 900 is configured to receive information through I/O interface 910. The information received through I/O interface 910 includes one or more of instructions, data, design rules, libraries of standard cells, and/or other parameters for processing by processor 902. The information is transferred to processor 902 via bus 908. EDA system 900 is configured to receive information related to a UI through I/O interface 910. The information is stored in computer-readable storage medium 904 as user interface (UI) 942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 900. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

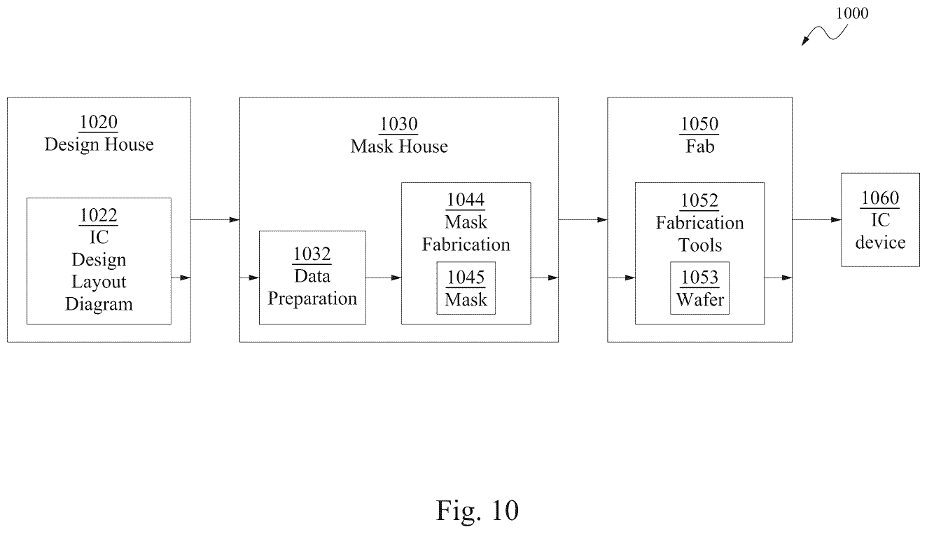

FIG. 10 is a block diagram of an integrated circuit (IC) manufacturing system 1000, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1000.

In FIG. 10, IC manufacturing system 1000 includes entities, such as a design house 1020, a mask house 1030, and an IC manufacturer/fabricator (“fab”) 1050, that interact with one another in the design, development, and manufacturing cycles and/or services related to manufacturing an IC device 1060. The entities in system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1020, mask house 1030, and IC fab 1050 is owned by a single larger company. In some embodiments, two or more of design house 1020, mask house 1030, and IC fab 1050 coexist in a common facility and use common resources.

Design house (or design team) 1020 generates an IC design layout diagram 1022. IC design layout diagram 1022 includes various geometrical patterns designed for an IC device 1060. The geometrical patterns correspond to patterns of metal, oxide, or semiconductor layers that make up the various components of IC device 1060 to be fabricated. The various layers combine to form various IC features. For example, a portion of IC design layout diagram 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1020 implements a proper design procedure to form IC design layout diagram 1022. The design procedure includes one or more of logic design, physical design or place-and-route operation. IC design layout diagram 1022 is presented in one or more data files having information of the geometrical patterns. For example, IC design layout diagram 1022 can be expressed in a GDSII file format or DFII file format.

Mask house 1030 includes data preparation 1032 and mask fabrication 1044. Mask house 1030 uses IC design layout diagram 1022 to manufacture one or more masks 1045 to be used for fabricating the various layers of IC device 1060 according to IC design layout diagram 1022. Mask house 1030 performs mask data preparation 1032, where IC design layout diagram 1022 is translated into a representative data file (“RDF”). Mask data preparation 1032 provides the RDF to mask fabrication 1044. Mask fabrication 1044 includes a mask writer. A mask writer converts the RDF to an image on a substrate, such as a mask (reticle) 1045 or a semiconductor wafer 1053. The design layout diagram 1022 is manipulated by mask data preparation 1032 to comply with particular characteristics of the mask writer and/or requirements of IC fab 1050. In FIG. 10, mask data preparation 1032 and mask fabrication 1044 are illustrated as separate elements. In some embodiments, mask data preparation 1032 and mask fabrication 1044 can be collectively referred to as mask data preparation.

In some embodiments, mask data preparation 1032 includes optical proximity correction (OPC) which uses lithography enhancement techniques to compensate for image errors, such as those that can arise from diffraction, interference, other process effects and the like. OPC adjusts IC design layout diagram 1022. In some embodiments, mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1032 includes a mask rule checker (MRC) that checks the IC design layout diagram 1022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1022 to compensate for limitations during mask fabrication 1044, which may undo part of the modifications performed by OPC in order to meet mask creation rules.

In some embodiments, mask data preparation 1032 includes lithography process checking (LPC) that simulates processing that will be implemented by IC fab 1050 to fabricate IC device 1060. LPC simulates this processing based on IC design layout diagram 1022 to create a simulated manufactured device, such as IC device 1060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1022.

It should be understood that the above description of mask data preparation 1032 has been simplified for the purposes of clarity. In some embodiments, data preparation 1032 includes additional features such as a logic operation (LOP) to modify the IC design layout diagram 1022 according to manufacturing rules. Additionally, the processes applied to IC design layout diagram 1022 during data preparation 1032 may be executed in a variety of different orders.

After mask data preparation 1032 and during mask fabrication 1044, a mask 1045 or a group of masks 1045 are fabricated based on the modified IC design layout diagram 1022. In some embodiments, mask fabrication 1044 includes performing one or more lithographic exposures based on IC design layout diagram 1022. In some embodiments, an electron-beam (e-beam) or a mechanism of multiple e-beams is used to form a pattern on a mask (photomask or reticle) 1045 based on the modified IC design layout diagram 1022. Mask 1045 can be formed in various technologies. In some embodiments, mask 1045 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1045 includes a transparent substrate (e.g., fused quartz) and an opaque material (e.g., chromium) coated in the opaque regions of the binary mask. In another example, mask 1045 is formed using a phase shift technology. In a phase shift mask (PSM) version of mask 1045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1044 is used in a variety of processes. For example, such a mask(s) is used in an ion implantation process to form various doped regions in semiconductor wafer 1053, in an etching process to form various etching regions in semiconductor wafer 1053, and/or in other suitable processes.

IC fab 1050 is an IC fabrication business that includes one or more manufacturing facilities for the fabrication of a variety of different IC products. In some embodiments, IC Fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1050 includes fabrication tools 1052 configured to execute various manufacturing operations on semiconductor wafer 1053 such that IC device 1060 is fabricated in accordance with the mask(s), e.g., mask 1045. In various embodiments, fabrication tools 1052 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1050 uses mask(s) 1045 fabricated by mask house 1030 to fabricate IC device 1060. Thus, IC fab 1050 at least indirectly uses IC design layout diagram 1022 to fabricate IC device 1060. In some embodiments, semiconductor wafer 1053 is fabricated by IC fab 1050 using mask(s) 1045 to form IC device 1060. In some embodiments, the IC fabrication includes performing one or more lithographic exposures based at least indirectly on IC design layout diagram 1022. Semiconductor wafer 1053 includes a silicon substrate or other proper substrate having material layers formed thereon. Semiconductor wafer 1053 further includes one or more of various doped regions, dielectric features, multilevel interconnects, and the like (formed at subsequent manufacturing steps).

In some embodiments, a memory device comprises a memory cell having a first transistor, a second transistor, a first capacitor and a second capacitor coupled with each other into a data storage circuit configured to store a datum. The memory cell further has a third transistor and a fourth transistor coupled with each other into a comparison circuit configured to perform a comparison of the datum stored in the data storage circuit with a search input datum. The memory device further comprises a back-end-of-line (BEOL) structure. The BEOL structure comprises at least a part of the memory cell.

In some embodiments, a method comprises performing front-end-of-line (FEOL) processing to obtain FEOL circuitry over a substrate; and performing back-end-of-line (BEOL) processing to obtain a BEOL structure over the FEOL circuitry and the substrate. The BEOL structure comprises a content-addressable memory (CAM) array.

In some embodiments, an integrated circuit (IC) device comprises a substrate, front-end-of-line (FEOL) circuitry over the substrate, and a back-end-of-line (BEOL) structure over the FEOL circuitry. The BEOL structure comprises first and second capacitors, first and second active structures, first through fourth gate electrodes, and first and second interconnect structures. The first and second active structures extend along a first direction, and are spaced from each other along a second direction transverse to the first direction. The first through fourth gate electrodes extend along the second direction. The first and fourth gate electrodes are over the first active structure. The second and third gate electrodes are over the second active structure. The first interconnect structure couples the third gate electrode to the first active structure and the first capacitor. The second interconnect structure couples the fourth gate electrode to the second active structure and the second capacitor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a memory cell having
a first transistor, a second transistor, a first capacitor and a second capacitor coupled with each other into a data storage circuit configured to store a datum, and
a third transistor and a fourth transistor coupled with each other into a comparison circuit configured to perform a comparison of the datum stored in the data storage circuit with a search input datum; and
a back-end-of-line (BEOL) structure, wherein the BEOL structure comprises at least a part of the memory cell.

2. The memory device of claim 1, wherein
the BEOL structure comprises an entirety of the memory cell.

3. The memory device of claim 1, further comprising:
a match line;
a first bit line; and
a second bit line,
wherein
the third transistor comprises:
a first source/drain coupled to the match line, and
a second source/drain coupled to the first bit line, and
the fourth transistor comprises:
a first source/drain coupled to the match line, and
a second source/drain coupled to the second bit line.

4. The memory device of claim 3, wherein
the data storage circuit comprises:
a first node configured to store a first logic state corresponding to the datum, and
a second node configured to store a second logic state corresponding to the datum and different from the first logic state,
the third transistor further comprises a gate coupled to the first node, and
the fourth transistor further comprises a gate coupled to the second node.

5. The memory device of claim 4, further comprising:
a word line;
wherein
the first transistor comprises:
a gate coupled to the word line,
a first source/drain coupled to the first node, and
a second source/drain coupled to the first bit line, and
the second transistor comprises:
a gate coupled to the word line,
a first source/drain coupled to the second node, and
a second source/drain coupled to the second bit line.

6. The memory device of claim 5, wherein
the first capacitor comprises:
a first electrode coupled to the first node, and
a second electrode coupled to a reference node configured to carry a reference voltage, and
the second capacitor comprises:
a first electrode coupled to the second node, and
a second electrode coupled to the reference node.

7. The memory device of claim 4, further comprising:
a control circuit coupled to the match line, the first bit line and the second bit line,
wherein
in a search operation, the control circuit is configured to
supply a search input signal corresponding to the search input datum to the first bit line, and
detect a comparison result of the comparison on the match line.

8. The memory device of claim 7, further comprising:
a word line;
wherein
the first transistor comprises:
a gate coupled to the word line,
a first source/drain coupled to the first node, and
a second source/drain coupled to the first bit line,
the second transistor comprises:
a gate coupled to the word line,
a first source/drain coupled to the second node, and
a second source/drain coupled to the second bit line,
the first capacitor comprises:
a first electrode coupled to the first node, and
a second electrode coupled to a reference node configured to carry a reference voltage,
the second capacitor comprises:
a first electrode coupled to the second node, and
a second electrode coupled to the reference node, and
in a write operation, the control circuit is configured to
through the word line, turn ON the first transistor and the second transistor, and
through the first bit line and the second bit line, write the first logic state and the second logic state correspondingly to the first node and the second node.

9. The memory device of claim 8, wherein
in a read operation, the control circuit is configured to
through the word line, turn ON at least one of the first transistor or the second transistor, and
through at least one of the first bit line or the second bit line, read at least one of the first logic state or the second logic state correspondingly from at least one of the first node or the second node.

10. The memory device of claim 9, further comprising:
a plurality of memory cells including the memory cell; and
a plurality of word lines comprising the word line,
wherein
each of the plurality of memory cells is coupled to
the first bit line, and
a corresponding word line among the plurality of word lines, and
in a computing-in-memory (CIM) operation, the control circuit is configured to
supply input voltages corresponding to input data to the plurality of word lines,
collect, on the first bit line, a first bit line current corresponding to a sum of currents output by the plurality of memory cells on the first bit line in response to the input voltages supplied to the plurality of word lines, and
based on the collected first bit line current, determine a product of the input data and weight data stored in the plurality of memory cells.

11. A method, comprising:
performing front-end-of-line (FEOL) processing to obtain FEOL circuitry over a substrate; and
performing back-end-of-line (BEOL) processing to obtain a BEOL structure over the FEOL circuitry and the substrate, wherein
the BEOL structure comprises a content-addressable memory (CAM) array.

12. The method of claim 11, wherein
said performing the BEOL processing comprises forming a plurality of memory cells of the CAM array, said forming the plurality of memory cells comprising
forming a plurality of transistors at a first level along a thickness direction of the substrate,
forming a plurality of capacitors at a second level along the thickness direction, the second level different from the first level, and
forming interconnect structures coupling the plurality of transistors to the plurality of capacitors.

13. The method of claim 11, wherein
said performing the BEOL processing comprises forming a plurality of memory cells of the CAM array, said forming the plurality of memory cells comprising, for each of the plurality of memory cells,
forming first through fourth transistors at a first level along a thickness direction of the substrate,
forming first and second capacitors at a second level along the thickness direction, the second level different from the first level,
forming a first interconnect structure coupling an electrode of the first capacitor to a source/drain of the first transistor and a gate of the third transistor, and
forming a second interconnect structure coupling an electrode of the second capacitor to a source/drain of the second transistor and a gate of the fourth transistor.

14. The method of claim 11, wherein
said performing the BEOL processing comprises forming a plurality of memory cells of the CAM array, said forming the plurality of memory cells comprising, for each of the plurality of memory cells,
forming first and second active structures extending along a first direction, the first and second active structures spaced from each other along a second direction transverse to the first direction,
forming first through fourth gate electrodes extending along the second direction, the first and fourth gate electrodes over the first active structure, and the second and third gate electrodes over the second active structure,
forming a first source/drain contact over the first active structure and adjacent to the first gate electrode, and
forming a first transverse interconnect over the third gate electrode, the first transverse interconnect coupling the third gate electrode to the first source/drain contact.

15. The method of claim 14, wherein
said forming the plurality of memory cells further comprises, for said each of the plurality of memory cells,
forming a first via over a first interconnect structure configured by the first source/drain contact and the first transverse interconnect, and
forming a first capacitor over the first via, the first capacitor comprising a first electrode over the first via, a first dielectric layer over the first electrode, and a second electrode over the first dielectric layer.

16. The method of claim 15, wherein
along a thickness direction of the substrate, the first capacitor overlaps the first gate electrode, the third gate electrode, the first active structure, and the second active structure.

17. The method of claim 15, wherein
said forming the plurality of memory cells further comprises, for said each of the plurality of memory cells,
forming a second source/drain contact over the first active structure and adjacent to the first gate electrode, wherein the first gate electrode is between the first source/drain contact and the second source/drain contact, and
forming a third source/drain contact over the second active structure and adjacent to the third gate electrode, and
said performing the BEOL processing further comprises:
forming a first bit line continuously extending along the second direction, the first bit line coupled to the second source/drain contact and the third source/drain contact.

18. The method of claim 17, wherein
said forming the plurality of memory cells further comprises, for said each of the plurality of memory cells,
forming a fourth source/drain contact over the second active structure and adjacent to the second gate electrode,
forming a second transverse interconnect over the fourth gate electrode, the second transverse interconnect coupling the fourth gate electrode to the fourth source/drain contact,
forming a second via over a second interconnect structure configured by the fourth source/drain contact and the second transverse interconnect,
forming a second capacitor over the second via, the second capacitor comprising a third electrode over the second via, a second dielectric layer over the third electrode, and a fourth electrode over the second dielectric layer,
forming a fifth source/drain contact over the second active structure and adjacent to the second gate electrode, wherein the second gate electrode is between the fourth source/drain contact and the fifth source/drain contact, and
forming a sixth source/drain contact over the first active structure and adjacent to the fourth gate electrode, and
said performing the BEOL processing further comprises:
forming a second bit line continuously extending along the second direction, the second bit line coupled to the fifth source/drain contact and the sixth source/drain contact.

19. An integrated circuit (IC) device, comprising:
a substrate;
front-end-of-line (FEOL) circuitry over the substrate; and
a back-end-of-line (BEOL) structure over the FEOL circuitry,
wherein the BEOL structure comprises:
first and second capacitors,
first and second active structures extending along a first direction, the first and second active structures spaced from each other along a second direction transverse to the first direction,
first through fourth gate electrodes extending along the second direction, the first and fourth gate electrodes over the first active structure, and the second and third gate electrodes over the second active structure,
a first interconnect structure coupling the third gate electrode to the first active structure and the first capacitor, and
a second interconnect structure coupling the fourth gate electrode to the second active structure and the second capacitor.

20. The IC device of claim 19, wherein
the first interconnect structure and second interconnect structure are L-shaped.
